(19) United States
(12) Patent Application Publication
(10) Pub. No.: US 2025/0180618 A1
(43) Pub. Date: Jun. 5, 2025

(54) THERMAL VACUUM CHAMBER FOR CRYOGENIC NEAR FIELD BEAM PATTERN MEASUREMENT AT TERAHERTZ FREQUENCIES

(71) Applicant: DUTCH TERAHERTZ INSPECTION SERVICES B.V., The Hague (NL)

(72) Inventors: Andrei Mikhailovitch BARYCHEV, Groningen (NL); Alena Vladimirovna BELITSKAYA, The Hague (NL)

(73) Assignee: DUTCH TERAHERTZ INSPECTION SERVICES B.V., The Hague (NL)

(21) Appl. No.: 18/907,398

(22) Filed: Oct. 4, 2024

Related U.S. Application Data
(60) Provisional application No. 63/542,730, filed on Oct. 5, 2023.

(51) Int. Cl. G01R 29/10; G01R 29/08

(52) U.S. Cl. CPC G01R 29/105; G01R 29/0821

(57) ABSTRACT

Particular embodiments described herein provide for a system, an apparatus, and a method for provide for a terahertz testing facility for cryogenic near field beam pattern measurement at terahertz frequencies. The vacuum chamber includes an anechoic chamber that includes an antenna under test, a testing chamber that includes testing equipment, and a thermal/radiation shield between the anechoic chamber and the testing chamber, wherein the thermal/radiation shield thermally separates the anechoic chamber and the testing chamber.

### CROSS-REFERENCE TO RELATED APPLICATION

This disclosure relates to Provisional Application No. 63/542,730, entitled “THERMAL VACUUM CHAMBER FOR CRYOGENIC NEAR FIELD BEAM PATTERN MEASUREMENT AT TERAHERTZ FREQUENCIES” filed in the United States Patent Office on Oct. 5, 2024, which is hereby incorporated by reference in its entirety.

### TECHNICAL FIELD

This disclosure relates in general to the field of testing chambers, more particularly, to a system, an apparatus, and a method to enable a thermal vacuum chamber for cryogenic near field beam pattern measurement at terahertz frequencies.

### BACKGROUND

A thermal vacuum chamber (TVAC) is a vacuum chamber in which the radiative thermal environment is controlled. The thermal vacuum chamber is an essential tool for the development, optimization, and validation of antennas used in various applications, from wireless communication systems to radar systems, satellite communication space and ground-based missions, etc. Typically, the thermal environment is achieved by passing liquids or fluids through thermal shrouds for cold temperatures. The most common applications of a thermal vacuum chamber are related to the tests of satellite performance, control of the thermal cycle and testing of components, subsystems, and complete satellites in a fully controlled environment. The tests are able to accurately reproduce the conditions of the space through the simultaneous control of pressure and temperature. The vacuum conditions inside the thermal vacuum chamber simulate the unique context in which a thermal exchange by irradiation and conduction is possible in the environment space.

It is essential to carry out tests before the launch of satellites to allow the satellites to be tested in all those conditions that could compromise the satellites performance. If the satellite's behavior in space is not examined in advance, the most frequent risk is the freezing or overheating of the satellite's components themselves.

### BRIEF DESCRIPTION OF THE DRAWINGS

To provide a more complete understanding of the present disclosure and features and advantages thereof, reference is made to the following description, taken in conjunction with the accompanying figures, wherein like reference numerals represent like parts, in which:

FIG. 1A-1E are a simplified block diagram of illustrating example details of a thermal vacuum chamber, in accordance with an embodiment of the present disclosure;

FIG. 2 is a simplified block diagram of a particular implementation of a device under test measurement system, in accordance with an embodiment of the present disclosure;

FIG. 3 is a simplified block diagram of a particular implementation of a scanner system, in accordance with an embodiment of the present disclosure;

FIG. 4 is a simplified block diagram illustrating example details of an alignment system, in accordance with an embodiment of the present disclosure;

FIG. 5 is a simplified block diagram of a radio frequency/intermediate frequency (RF/IF) system, in accordance with an embodiment of the present disclosure;

FIG. 6 is a simplified block diagram of control and support engine, in accordance with an embodiment of the present disclosure;

FIG. 7 is a simplified block diagram of a main body of the thermal vacuum chamber, in accordance with an embodiment of the present disclosure;

FIGS. 8A and 8B are simplified block diagrams illustrating example details of a movable shield, in accordance with an embodiment of the present disclosure;

FIGS. 9A and 9B are simplified block diagrams illustrating example details of a movable shield, in accordance with an embodiment of the present disclosure;

FIG. 10 is a simplified block diagram illustrating example details of a movable shield, in accordance with an embodiment of the present disclosure;

FIGS. 11A and 11B are simplified block diagrams illustrating example details of a hexapod support structure for the scanner system (left) and general view of the scanner (right) in accordance with an embodiment of the present disclosure;

FIG. 12 is a simplified block diagram illustrating example details of a scanner system frame, in accordance with an embodiment of the present disclosure;

FIG. 13 is a simplified block diagram illustrating example details of a counter weight system arrangement mounted in a thermal vacuum chamber, in accordance with an embodiment of the present disclosure;

FIGS. 14A-14C are simplified block diagrams illustrating example details of a counterbalance support structure, in accordance with an embodiment of the present disclosure;

FIG. 15 is a simplified block diagram illustrating example details of an alignment system, in accordance with an embodiment of the present disclosure;

FIGS. 16A and 16B are simplified block diagrams illustrating example details of an alignment system, in accordance with an embodiment of the present disclosure;

FIG. 17 is a simplified block diagram illustrating example details of a shroud cooling layout, in accordance with an embodiment of the present disclosure;

FIG. 18 is a simplified block diagram illustrating example details of a vacuum control system, in accordance with an embodiment of the present disclosure;

FIG. 19 is a simplified block diagram illustrating example details of device under test rotating platform, in accordance with an embodiment of the present disclosure;

FIGS. 20A-20C are simplified block diagrams illustrating example details of a base plate cart, in accordance with an embodiment of the present disclosure;

FIGS. 21A and 21B are simplified block diagrams illustrating example details of an anechoic chamber mounted in a thermal vacuum chamber, in accordance with an embodiment of the present disclosure;

FIG. 22 is a simplified block diagram illustrating example details of a baseline thermal design of the system, in accordance with an embodiment of the present disclosure;

FIG. 23 is a simplified block diagram illustrating example details of a baseline thermal design of the system, in accordance with an embodiment of the present disclosure;

FIG. 24 is a simplified diagram illustrating the kinematic support structure of the movable shield, in accordance with an embodiment of the present disclosure;

FIG. 25 is a simplified 3D rendering illustrating a SKID frame of the gas regulation system and an electrical control scheme, in accordance with an embodiment of the present disclosure;

FIG. 26 is a simplified flowchart illustrating potential operations to enable cryogenic near field beam pattern measurement at terahertz frequencies, in accordance with an embodiment of the present disclosure; and

FIG. 27 are simplified tables illustrating example details for different configurations of coatings, in accordance with an embodiment of the present disclosure.

The FIGURES of the drawings are not necessarily drawn to scale, as their dimensions can be varied without departing from the scope of the present disclosure.

### DETAILED DESCRIPTION

The following detailed description sets forth examples of apparatuses, methods, and systems relating to enabling a thermal vacuum chamber for cryogenic near field beam pattern measurement at terahertz frequencies in accordance with an embodiment of the present disclosure. Features such as structure(s), function(s), and/or characteristic(s), for example, are described with reference to one embodiment as a matter of convenience; various embodiments may be implemented with any suitable one or more of the described features.

### Overview

An apparatus, system and method can help enable a thermal vacuum chamber for cryogenic near field beam pattern measurement at terahertz frequencies to allow users to map complex electrical fields in the near field of an antenna aperture. This map can be subsequently used to analyze beam properties in all principal planes of the system, especially the focal plane, the aperture plane, and the far field plane, which is specifically relevant for the scientific goals of the instruments in satellites for both future space and Earth observation missions, as well as various other applications, such as wireless communication systems, radar systems, satellite communication space and ground-based missions, etc. Currently, both future space and Earth observation missions are moving up in frequency and the requirements for testing the instruments in satellites goes well beyond those of the current testing facilities. The consequence is that the accuracy required on the characterization and validation of the instruments in satellites has become very demanding and today no tools or facilities exist to fully measure some of the instruments in some satellites. To achieve the required precision on the science, these instruments in the satellites need a complete antenna characterization under operational conditions (vacuum, cryogenic temperatures, etc.), a capability that is not available today.

As disclosed herein, a terahertz testing facility can be used to test the instruments in the satellites within the terahertz frequencies while maintaining a cryogenic environment (very low temperatures, often close to absolute zero). The terahertz testing facility can provide a controlled, isolated, and repeatable environment that allows engineers and researchers to obtain precise and trustworthy measurements of characteristics of an antennae or other hardware under test. The terahertz testing facility is an essential tool for the development, optimization, and validation of antennas used in various applications, from wireless communication systems to radar systems and satellite communication as well as other types of devices.

In some examples, the terahertz testing facility can include a cryostat device, an anechoic chamber, an X,Y,Z-scanner system, a moveable shield, a data acquisition system, a control and automation system as well as analysis, and software tools. The cryostat device can be used to cool down a device under test (e.g., an antenna) and the environment surrounding the device under test in the anechoic chamber of the terahertz testing facility to cryogenic temperatures and to maintain the very low cryogenic temperatures. In some examples, liquid helium or liquid nitrogen could be used as the cooling agents to help reach and maintain the cryogenic temperatures. In some examples, the design of the cryostat device helps to allow the device under test to be mounted and adjusted while maintaining the low cryogenic temperatures.

The anechoic chambers are specialized environments designed for testing and measuring the performance of antennas and wireless communication devices as well as other devices. The anechoic chambers are designed to minimize external interference and reflections, allowing accurate characterization of antenna behavior as well as the characterization of the behavior of other devices. In an example, one or more parts of the anechoic chambers' walls, ceiling, and floor can be treated with specialized anechoic materials that absorb electromagnetic waves to minimize reflections. This treatment helps to ensure that the chamber simulates a free-space environment as closely as possible. The anechoic materials used in the anechoic chambers can have high absorption characteristics across the frequency range that is being tested. The anechoic chambers can be configured to provide isolation (or at least partial isolation) from external electromagnetic interference, including radio frequency (RF) signals from surrounding environments and electronic devices as well as to help prevent external signals from entering the anechoic chambers and interfering with measurements of the antenna being tested. The anechoic chambers can include a “quiet zone” within the chamber where measurements are taken. The quiet zone is a region inside the anechoic chambers that has low levels of electromagnetic interference and minimal reflections. The size of the quiet zone depends on design constrains and the application and size of the antenna or other device being tested.

In an example, where the device under test is an antenna, the anechoic chambers can be equipped with calibrated measurement instruments, such as vector network analyzers (VNAs), spectrum analyzers, and anechoic chamber antenna measurement systems (ACAMS). These instruments are used to characterize antenna performance for measuring antenna properties like reflection coefficient, transmission coefficient, and radiation patterns. In some examples, specialized VNAs capable of operating at terahertz frequencies and low temperatures may be used in the anechoic chambers. In some examples, terahertz sources and detectors suitable for cryogenic temperatures can be used for generating and measuring terahertz signals. The terahertz sources and detectors can include frequency multiplier chains, photomixers, or other terahertz generation and detection techniques compatible with low cryogenic temperatures.

The anechoic chambers can include an adjustable positioner system for orienting an antenna under test or other devices under test. The adjustable positioner system can allow the antenna under test or other devices under test to be rotated and tilted to capture radiation patterns in different planes. A turntable is often used as part of the adjustable positioner system to rotate the antenna under test or other devices under test horizontally, allowing measurements to be taken at various azimuth angles. An elevation system can be used as part of the adjustable positioner system to tilt the antenna or other device vertically to capture measurements at different elevation angles. The anechoic chamber allows for testing of both linear and circular polarizations to capture the complete performance of the antenna under test or other devices under test. By controlling the testing environment provided by the anechoic chamber, consistency and reproducibility of measurements of antennas under test or other devices under test can be achieved and the system allows for accurate comparisons between different antennas and devices.

The X,Y,Z scanner system can be located in a portion of the terahertz testing facility (the testing chamber) that remains at room temperature (˜300 K) during testing of the antenna or other device and can include an RF test probe mounted on a top portion of the of the X,Y,Z scanner system. During testing of the antenna or other device, an H-shaped bridge/gantry scanner arrangement can be used as part of the XYX scanner system. In some examples, a radio frequency test probe can be attached on top of the Z-stage of the X,Y,Z-plane scanner system. A planar scan is measured according to a “meander” pattern where the probe moves on the fly from left to right, moves one step up or down, moves on the fly from the right to the left, et cetera. For the X-stage, a linear motor that only dissipates heat while accelerating or breaking is used. The Y- and Z-stages are both operated by stepper motors that dissipate heat at one point only. The heat that is generated by the Z-stage can be dissipated radiatively due to its low power consumption and duty cycle.

The scanner unit of the X,Y,Z-plane scanner system can be mounted on a hexapod (Stewart platform) support structure. By loosening/tightening bolts on the hexapod support structure, the hexapod support structure can be used to adjust the orientation of the scanner plane in all six spatial degrees of freedom. However, the main function of the hexapod support structure is to minimize the amount of deformations under any loading that may occur, in particular when cycling between atmospheric pressure and vacuum. Because of the structure of the hexapod support structure, the scanner plane can move somewhat, but not bend. The X,Y,Z-plane scanner system can be unbolted from/bolted on the hexapod support structure. It is also possible to dismount the whole X,Y,Z-plane scanner system including the hexapod support structure. The frame of the X,Y,Z-plane scanner system can include a linear variable differential transformers (LVDT) position measurements system a sophisticated. The linear variable differential transformers position measurements system can measure position and tilts of the scanner frame as a whole and in particular the linear variable differential transformers position measurements system sensor allows for measurement of the bending radius of x-axis.

In some examples, the X,Y,Z scanner system can include a counterweight system and device under test alignment system. The counterweight system can unload the XYZ scanner from heavy moveable shield components (250 kg estimated max unload weight). The device under test alignment system can consist of several pentaprizms and flat mirrors that are mounted on the different parts of an X,Y,Z stage. The device under test alignment system can be illuminated from a theodolite/laser beam through a vacuum compatible optical illuminator window.

The movable shield can be a thermal/radiation shield that is configured as a moveable heat barrier between the anechoic chamber of the terahertz testing facility and the testing chamber that houses the X,Y,Z-plane scanner system. More specifically, the movable shield allows radio frequency test probe to be moved around in a 1000×1000 mm field, while the cryogenic environment of the anechoic chamber is not compromised. The moveable shield can have a harmonic design to allow for ease of manufacturing and ease of operation. In addition, the design and profile of surface normals (the imaginary line perpendicular to a flat surface or perpendicular to the tangent plane at a point on a non-flat surface of the movable shield) on the moveable shield do not point towards the receiver, thereby alleviating the risk of reflections distorting the beam pattern measurements.

The movable shield thermally separates the two portions of the terahertz testing facility and can provide thermal isolation from a three-hundred (300) Kelvin (K) environment. In addition, the movable shield can provide no reflection, or almost no reflection, from the antenna under test or other device under test side at submm wavelengths and at the same time provide access for a radio frequency probe mounted on the X,Y,Z-plane scanner system for measurement of beam patterns from the antenna under test. A first side of movable shield (internal to the shroud) can be covered by absorbing material (e.g., Stycast/SiC) and a second side of the movable shield can be polished to reduce emissivity. The movable shield can be configured to function much like an accordion or pleated blinds, but in two dimensions and with a small aperture that moves with the antenna under test. In some examples, the movable shield is attached to and moves with the X,Y,Z-plane scanner system. The inside of the movable shield can be coated with absorber material and the outside of the shield can be by multiplayer insulation.

In some examples, the movable shield can include plates that are overlapping on the side of the movable shield that is facing the antenna under test or device under test (big, small, big, small, et cetera), so that the joints of the plates can also be covered by absorption coating, which results in continuous or near continuous reflection. It is important to note that the angle between two neighboring plates should not exceed ninety degrees (90°) or become as small as fourteen degrees (14°). In this regime, the movable shield's response to electromagnetic radiation might become very polarization dependent because the metal strips form a vertical grid that reflects vertically polarized light much more than it reflects horizontally polarized light. To mitigate this problem, the plates on the movable shield can be bent near the end of the shield somewhat, but only on the side of the movable shield that is facing the antenna under test or device under test device under test. Hence, the movable shield can be cooled conductively and may be placed within the lid of the anechoic chamber.

The data acquisition system can be a high-speed data acquisition system capable of capturing and processing terahertz signals at cryogenic temperatures. The data acquisition system can be configured to interface with the measurement instruments used during testing of the antenna and record the testing data for analysis.

The control and automation system can be configured to manage and monitor the cryogenic cooling, data acquisition, and measurement processes to help ensure consistency and reliability in measurements. The control and automation system can include a transient state and a steady state. The transient state refers to everything that concerns pumping down from atmospheric pressure to ultimate pressure and vice versa, and cooling down from room to cryogenic temperature and vice versa. These transient state operations can take several hours and can often take place unsupervised. With safety reasons in mind, all pumps, sensors and actuators that are involved in the transient state operations can be controlled by a fault-tolerant (double redundant) programmable logic controller.

A state machine control logic is implemented in a programable logic controller (PLC) module as well as in the control software. The state machine control logic includes state definitions, for the nominal automatic transitions between states upon successful completion (e.g., “pumping”, “cool down” etc.). In some examples, emergency routines and states are implemented that allow the system to exit any existing control state in case of an abnormal condition is met at any of the critical control hardware as well as when an emergency switch knob is activated. The emergency switch knob can be located near the facility in a clean room as well as near a SKID frame gas flow regulation unit at the technical level of the clean room. The major equipment states such as normal operations, warnings, and alarms can be indicated by a three color indicator installed near the facility which visible from large distance and from security cameras.

The steady state portion of the control and automation system includes the distributed temperature sensors and heater networks used to maintain stable temperature gradients, the portions of the system for moving the scanner and the azimuthal rotator, and parts of the RF/IF circuits. The steady state portion of the control and automation system can be controlled from one or more lab computers. In some examples, components include an Ethernet/LAN connection so that the communication over TCP/IP from any programming language is possible.

In some examples, specialized software tools for terahertz antenna analysis and data processing allow for interpreting the collected data and extracting meaningful results from tests. It should be noted that accurate calibration standards are crucial for validating and calibrating the measurement setup of the system and these standards should be compatible with both terahertz frequencies and cryogenic temperatures. Also, in the near-field region of an antenna, the electromagnetic field characteristics can vary significantly from those in the far-field region where antennas are normally operated. The anechoic chambers help ensure that measurements are taken in the far-field region, where antenna behavior is better understood and characterized.

### Example Systems, Apparatuses, and Methods

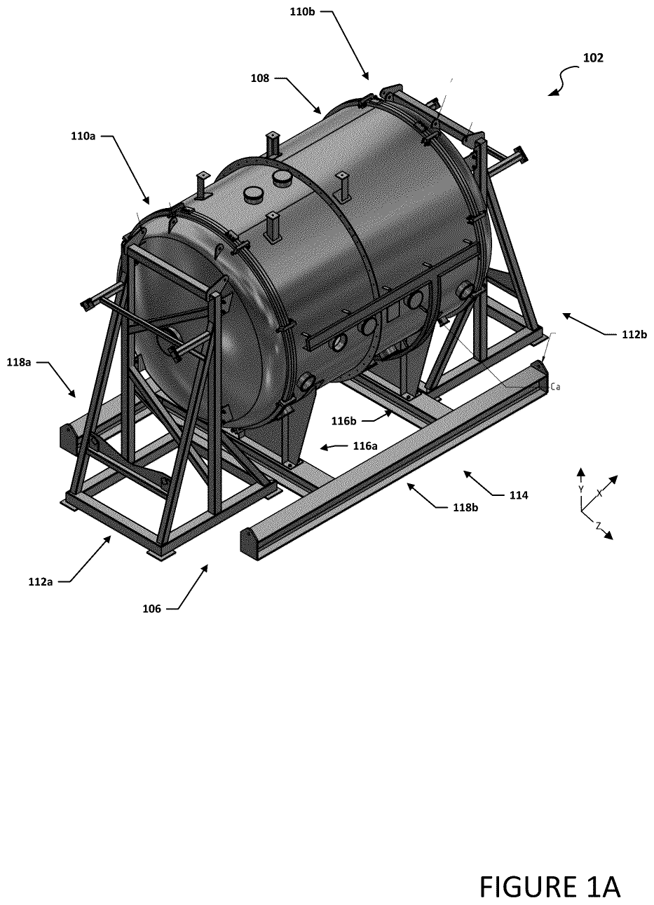

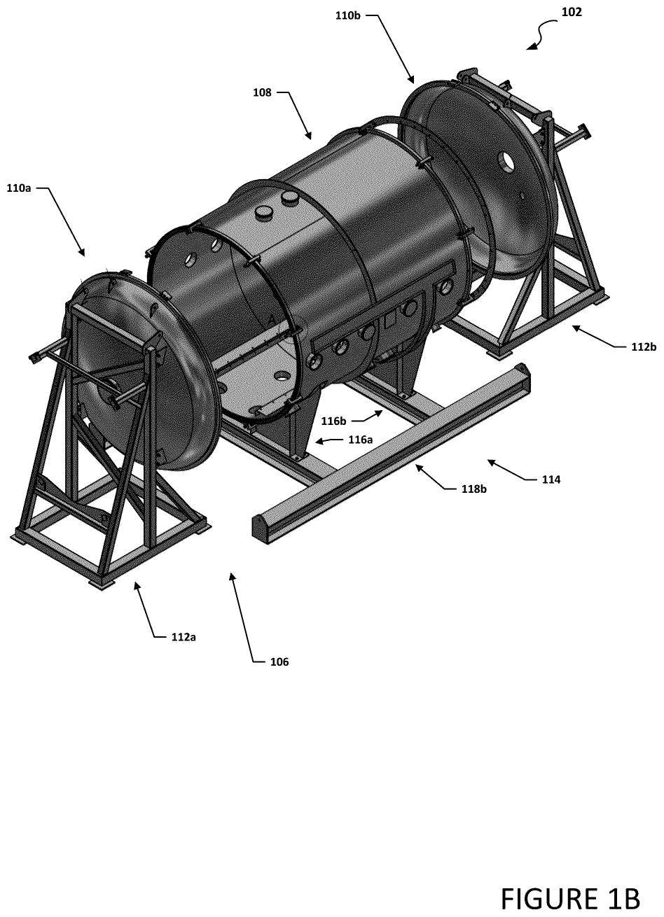

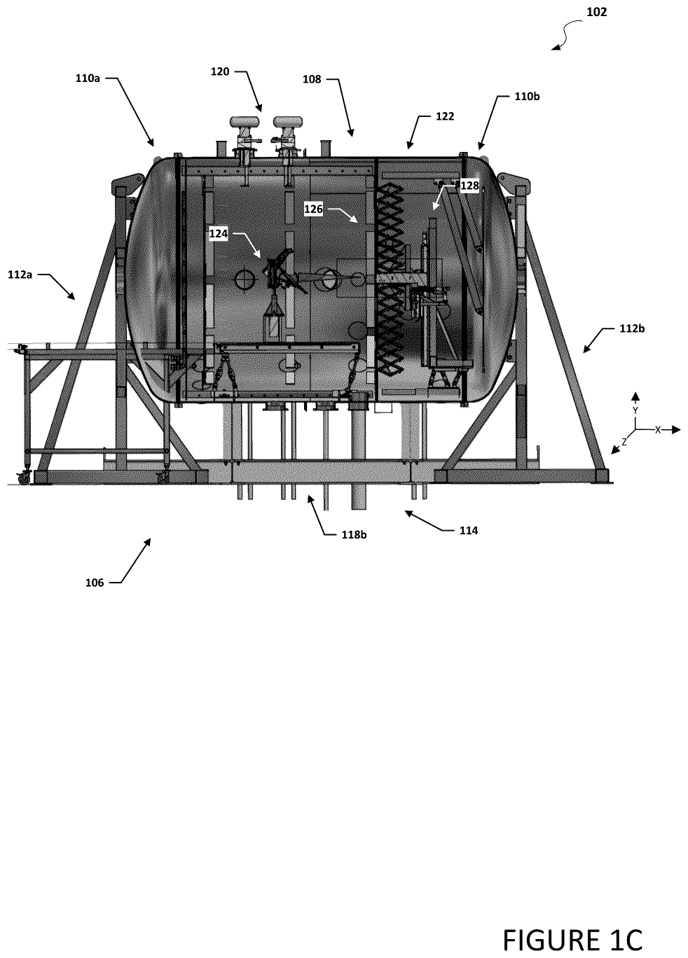

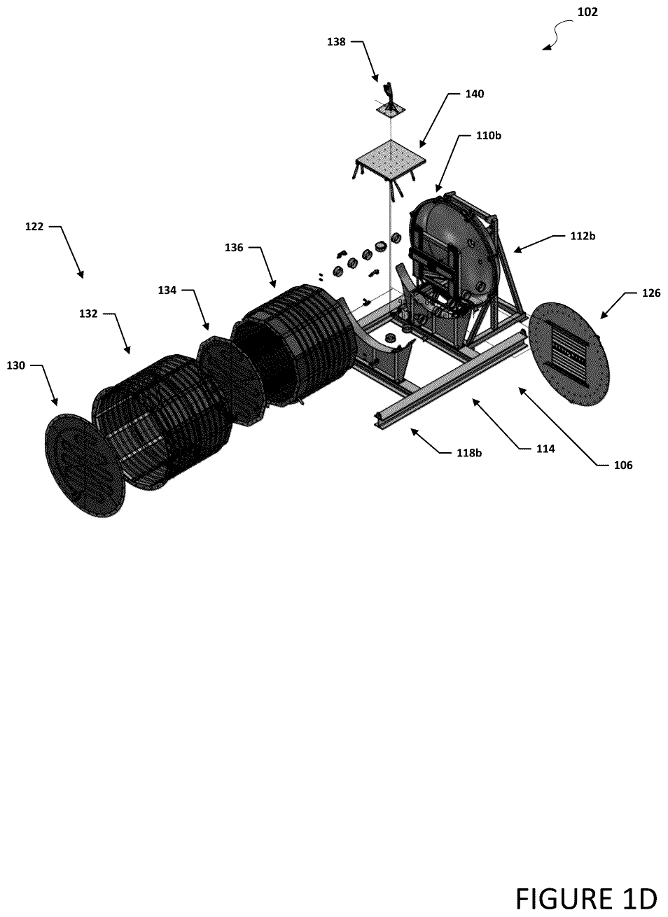

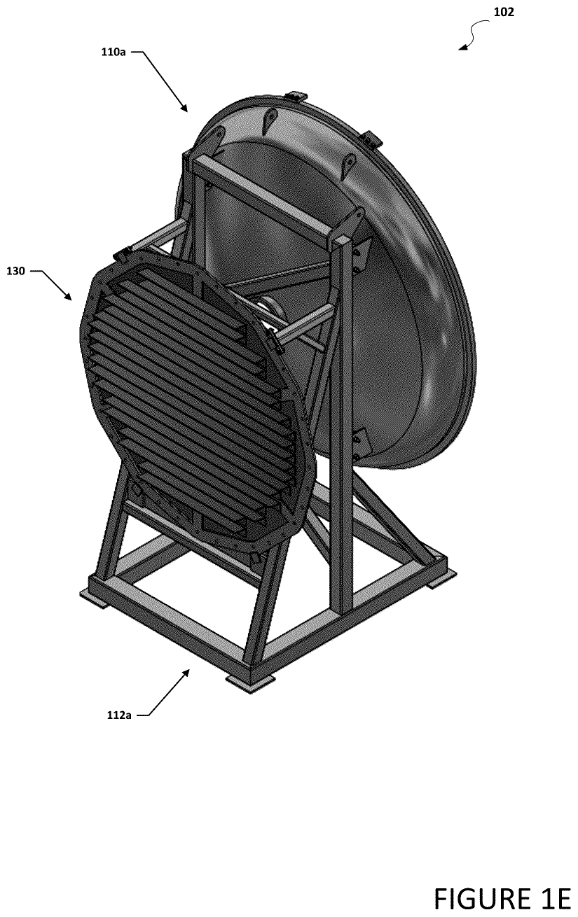

FIGS. 1A and 1B are simplified block diagram of a particular non-limiting terahertz testing facility 102. The terahertz testing facility 102 can terahertz testing facility 102be supported by a support structure 106. The terahertz testing facility 102 can include a main body 108, a first lid 110a, and a second lid 110b. The support structure 106 can include a first lid support structure 112a, a second lid support structure 112b, and a main body support structure 114. The main body support structure 114 can include a first bracing and support structure 116a, a second bracing and support structure 116b, a first skid 118a, and a second skid 118b. In a specific non-limiting example, the dimensions of the terahertz testing facility 102 are 2800 mm in inner diameter and 4612 mm in total length, not counting the support structures. Including the terahertz testing facility 102 and the support structure 106, the terahertz testing facility 102 is 6694 mm long, 3400 mm wide and 3861 mm high.

The first lid support structure 112a can support the first lid 110a and the second lid support structure 112b can support the second lid 110b. The first bracing and support structure 116a and the second bracing and support structure 116b can support the main body 108 of the terahertz testing facility 102. The first skid 118a and the second skid 118b can add structural stability to the main body support structure 114.

As illustrated in FIG. 1B, the first lid support structure 112a can support the first lid 110a and the second lid support structure 112b can support the second lid 110b. The first lid support structure 112a and the second lid support structure 112b can move to allow the first lid 110a and the second lid 110b to be removed from the main body 108 of the terahertz testing facility 102. The first lid support structure 112a and the second lid support structure 112b are moved independently of each other. More specifically, the first lid support structure 112a can move to allow the first lid 110a to be removed from the main body 108 of the terahertz testing facility 102 and/or the second lid support structure 112b can be moved to allow the second lid 110b to be removed from the main body 108 of the terahertz testing facility 102.

Turning to FIG. 1C, FIG. 1C is a simplified block diagram illustrating a cutaway view of a particular non-limiting terahertz testing facility 102. The terahertz testing facility 102 can include the terahertz testing facility 102 and the support structure 106. The terahertz testing facility 102 can include the main body 108, the first lid 110a, and the second lid 110b. The support structure 106 can include the first lid support structure 112a, the second lid support structure 112b, and the main body support structure 114. The main body support structure 114 can include the first bracing and support structure 116a (not referenced), the second bracing and support structure 116b (not referenced), the first skid 118a (not shown), and the second skid 118b.

The main body 108 can include an anechoic chamber 120 and a testing chamber 122. The anechoic chamber 120 can include a device under test 124 (e.g., an antenna). The device under test 124 can be one or more instruments that may be used in a satellite, especially an antenna. The testing chamber 122 can include an X,Y,Z-plane scanner system 128. The X,Y,Z-plane scanner system 128 can include one or more testing instruments. The X,Y,Z-plane scanner system 128 is used to test the device under test 124 in the anechoic chamber 120. A thermal/radiation shield 126 can divide the anechoic chamber 120 from the testing chamber 122.

Turning to FIG. 1D, FIG. 1D is a simplified block diagram illustrating an exploded view of a portion of particular non-limiting terahertz testing facility 102. The terahertz testing facility 102 can include the terahertz testing facility 102 (not shown) and the support structure 106. The terahertz testing facility 102 can include the main body 108 (not shown), the first lid 110a (not shown), and the second lid 110b. The support structure 106 can include the first lid support structure 112a (not shown), the second lid support structure 112b, and the main body support structure 114. The main body support structure 114 can include the first bracing and support structure 116a (not referenced), the second bracing and support structure 116b (not referenced), the first skid 118a (not referenced), and the second skid 118b.

The main body 108 can include the anechoic chamber 120 and the testing chamber 122. The anechoic chamber 120 can include a first lid shroud 130, a first chamber main body shroud 132, and an instrument turning support 138. The instrument turning support 138 is used to position the device under test 124 (shown in FIG. 1C) in the anechoic chamber 120 for testing. The instrument turning support 138 can be secured to a support structure 140. The testing chamber 122 can include a shield shroud 134 and a second chamber main body shroud 136.

Turning to FIG. 1E, FIG. 1E is a simplified block diagram illustrating the first lid 110a supported by the first lid support structure 112a. When the first lid shroud 130 is not in use, the first lid shroud 130 can be stored on the first lid support structure 112a. Similarly, when the shield shroud 134 is not being used, the shield shroud 134 can be stored on the second lid support structure (not shown). In some examples, if there is a second lid shroud, the second lid shroud can be stored on the second lid support structure.

It is to be understood that other embodiments and implementations may be utilized, and structural changes may be made without departing from the scope of the present disclosure. Substantial flexibility is provided by the system and method in that any suitable arrangements and configuration may be provided without departing from the teachings of the present disclosure. For purposes of illustrating certain example techniques of a terahertz testing facility for cryogenic near field beam pattern measurement at terahertz frequencies, the following foundational information may be viewed as a basis from which the present disclosure may be properly explained.

Currently, both future space and Earth observation missions are moving up in frequency and the requirements for these instruments go well beyond those of related THz instruments developed up to now. The consequence is that the accuracy required on the characterization/validation of these instruments has become very demanding and currently, no tools or facilities exist to fully measure the proposed instruments. To achieve the required precision on the science, these instruments need a complete antenna characterization under operational conditions (vacuum, cryogenic temperatures) that current facilities cannot provide.

A system, method, apparatus, means, etc. to enable a terahertz testing facility for cryogenic near field beam pattern measurement at terahertz frequencies can help resolve these issues (and others). In an example, the terahertz testing facility for cryogenic near field beam pattern measurement at terahertz frequencies can include a vacuum vessel and support structure. The vacuum vessel can be cylindrical and made of stainless steel, aluminum, titanium, a specialized alloy (e.g., a nickel-based alloy), advanced composite materials or some other material that allows the vacuum vessel to maintain the desired level of vacuum for the particular application and the environment in which it may be used.

The vacuum vessel has lids on both ends, which can be removed. For example, the lids can be removed with a crane or pneumatically with a pneumatically supported transport system. In some examples, the lids rest on separate support structures. Before the system is evacuated, the lids are clamped to the main body of the vacuum vessel. Each of the lids can include a seal to help seal the environment inside the terahertz testing facility from the environment outside of the terahertz testing facility. If the lids are circular, the seal can be O-rings. In some examples, the seal can be seated in a groove on the main body of the cylindrical vacuum vessel. When compressed, the sealing members create a leak-tight seal at the interface between the lid and the main body of the cylindrical vacuum vessel.

The terahertz testing facility can include a X,Y,Z-plane scanner system, a thermal shroud, a counterweight system, a thermal/radiation shield, a device under test (e.g., an antenna) alignment system, and a thermo-regulation system. In some examples, the terahertz testing facility can also include an intermediate 80K level shroud on an outside portion of the thermal/radiation shield that includes the device under test. The terahertz testing facility can also include an X,Y,Z-plane scanner system with a radio frequency test probe mounted on top of Z stage of the scanner. The test probe can be positioned on the Z-stage and can be mounted behind the heat shield.

A thermal shroud can be used to house the device under test. In some examples, the thermal shroud is a cylindrical thermal shroud. The thermal shroud can be cooled by a mixed phase liquid/gas nitrogen circuit and wrapped in multilayer insulation blankets. Inside, temperatures down to 80 K can be obtained. To suppress standing waves, the thermal shroud can be coated with absorber panels/coating on the inside of the thermal shroud. This allows the shroud acts as an anechoic chamber to stop or mitigate reflections or echoes of either sound or electromagnetic waves.

The terahertz testing facility can include a thermal/radiation shield in between portions of the terahertz testing facility and the thermal/radiation shield can thermally separate the two portions of the terahertz testing facility. The thermal/radiation shield is configured to function much like an accordion/pleated blinds, but in two dimensions and with a small aperture that moves with the test source. The thermal/radiation shield can be attached to and move with the X,Y,Z-plane scanner system. The inside of the thermal/radiation shield can be coated by absorber material and the outside by multilayer insulation. An intermediate 80 K level shroud can surround the anechoic chamber. The shroud can enable below 80 K operation of the anechoic chamber and down to 4 K operation of the device under test. In some examples, the device under test and the anechoic chamber can be cooled with mechanical cryo-coolers. The 80 K level shroud can be cooled by a mixed phase nitrogen circuit. The terahertz testing facility can also include a thermo-regulation system that distributes and regulates the flow of liquid/gaseous nitrogen mixture.

The device under test alignment system can include of several pentaprizms and flat mirrors that are mounted on the different parts of an X,Y,Z-plane stage. The system can be illuminated from a theodolite/laser beam through a vacuum compatible optical illuminator window on the terahertz testing facility. The terahertz testing facility can also include an optical alignment system (to reference the coordinate system of the test probe to the scan geometry), a radio frequency/intermediate frequency (RF/IF) system and other required control and support equipment (metrology readout and control hardware+software).

The system is highly modular. The different subsystems can be developed and used separately from each other. For example, to use the X,Y,Z-plane scanner for a different purpose, a user can simply remove the X,Y,Z-plane scanner from the terahertz testing facility. To facilitate such processes, all mechanical, electrical, vacuum and gas interfaces can be attached to the cylindrical part of the terahertz testing facility.

In a specific example implementation, the anechoic chamber is placed into the terahertz testing facility. The anechoic chamber can be supported by heat isolating material support legs. The anechoic chamber can be made from aluminum alloy, copper, fiber glass, or some other material. For aluminum alloy, the aluminum alloy can be polished outside to reduce emissivity to the level of approximately 0.05. The inside of the anechoic chamber can be coated by Stycast/SiC grains anti-reflection coating, carbon-loaded materials, multilayer dielectric coating, or some other material and have emissivity very close to unity.

Cooling the anechoic chamber can be achieved by a mixed phase liquid/gas Nitrogen circuit, wrapped around the cylinder of the terahertz testing facility, and also connected to the cover of the terahertz testing facility. On a first side, the terahertz testing facility is shielded by the moveable shield which is attached to the X,Y,Z-plane scanner system or has its own motorized stage. The purpose of the thermal/radiation shield to provide no reflection or minimal reflection from the side that includes the device under test at submm wavelengths, provide thermal isolation from 300K environment, and provide access to the radio frequency probe mounted on the X,Y,Z-plane scanner system for beam pattern measurements. The shield is provided by a separate mixed phase cooling circuit or uses the same cooling system as the anechoic chamber. The device under test is mounted inside the anechoic chamber on a heat isolating support and cooled by a separate mixed phase exchange circuit attached to a heat exchange plate. Due to the choice of the cooling agent, the lowest achievable temperature in such an arrangement is above liquid nitrogen evaporation temperature and is of order of 80K. An electrical thermometer/heater system can be used for additional stabilization of the temperature of the device under test on short time scales if so desired.

For a first order thermal balance estimate, the moveable shield can be considered as an integral part of the anechoic chamber with the same properties as the wall of the anechoic chamber. In a specific non-limiting example, considered anechoic chamber dimensions of 1.5 m length and 2.6 m diameter the total wall area is 22 m2. Taking 0.1 for emissivity of polished stainless steel and 0.05 for emissivity of polished Aluminium at low temperature, one can obtain the heat load of 360 W at 80K. Further reduction of this heat load can be achieved with the multi-layer insulation blanket. With a twenty (20) layer multi-layer insulation, blanket parameters and radiation transfer model the radiation heat load becomes 100 W at 80K. This estimate is conservative and does not include improvement of emissivity of the metal layer upon cooling down to cryogenic temperatures. Heat load for an ideal 20-layer multi-layer insulation blanket would be as low as 20 W.

The multi-layer insulation blanket should not have to be folded anywhere because thermal shorting or damage may occur. With this in mind, two semicircle shaped multi-layer insulation blankets may be used for the back/cooling flange of the anechoic chamber and one or more (e.g., six) rectangular blankets for the cylindrical part of the anechoic chamber. The joints are sealed by low outgassing and cryogenically compatible adhesive tape. Standoffs are not required but may be used. A similar approach for the other lid may be used, but with accommodations for the thermal/radiation shield.

The rectangular multi-layer insulation blankets can contain several holes, as well as the anechoic chamber itself, so that the required wiring can be brought inside the terahertz testing facility. If a hole corresponds to a spare/blinded nozzle, a small multi-layer insulation blanket-covered plate can be mounted on the anechoic chamber to block off the hole. The plates (and thus the holes in the multi-layer insulation blanket) must be undersized a bit so that they can later be taken out through the nozzle.

To provide an estimate for heat load through conductive support, the anechoic chamber can be supported by four plates of 10×100×100 mm3 made out of glass fiber reinforced polymer (GRFP) of G-10 type. Taking conductivity of this material to be 1 W/K/M, the total conductive load is negligible compared to the radiative load (e.g., the total conductive load can be three (3) W at eighty (80) K). Additional cooling power, available from a separate heat exchange circuit can be used to pick up internal dissipated power from the device under test and regulate the temperature of the device under test.

Four (4) K operations at the level of the device under test can be achieved by mechanical cryocooler as a powerful cryocooler. The cryocooler can be connected by its second stage to the device under test providing a desired cooling power. In some examples, an additional shroud can be added. In other examples, the anechoic chamber can be on mixed phase liquid nitrogen cooler and the cryocooler second stage cooling can be used for the device under test.

For heat intercept of heat from the device under test, an additional shroud connected to a mixed phase nitrogen circuit can be introduced. The mixed phase nitrogen circuit can have a similar one hundred (100) W heat load as a baseline thermal design reaching eighty (80) K, however both inner and outer surface of this shroud and outer surface of the anechoic chamber can be made shiny and a multi-layer insulation blanket can be used in between. This allows the system to achieve very low radiation heat load on the ANEC (2.3 W @ 40K without). In turn this allows the system to reach forty (40) K in the anechoic chamber with significant margin. A forty (40) K, the anechoic chamber temperature allows to further decrease the load on the device under test. Cooling the thermal/radiation shield lower than eighty (80) K would pose significant technical challenge. As will be described in the moveable shield design, it is inevitable that three-hundred (300) K background will leak through the slots between plates in the thermal/radiation shield, producing additional load, that needs to be carefully analyzed before attempting to switch over to a four (4) K system. One remedy to this leakage is to use a floating shield made from Gore-Tex membrane or some other similar type membrane. Gore-Tex is highly transparent to submm THz radiation, but completely opaque to near IR where most of radiation energy would be at eighty (80) K. In addition, Gore-Tex has extremely low heat conductivity, which enables effective heat disconnect between front and back surface of the membrane. As result, membrane assumes intermediate temperature between the shield and the device under test reducing heat load analogous to 2-layer multi-layer insulation blanket but almost not disturbing the device under test beam pattern at submm wavelengths. In order to operate the device under test at 4 K, it is possible to add a mechanical cryocooler to the system. Depending on radiation properties of the device under test, this alone may not be enough to reach 4K and additional shroud between the anechoic chamber and the device under test would be required for the 4K system with device beam pattern capability.

For the detailed radiation thermal balance calculations, the Stefan Boltzmann law (1) was used as well as the parallel plate heat transfer equation (2) and heat transfer using layer conductivity (3):

$$P = ε 1 σ ( {T}_{1}^{4} - {T}_{2}^{4} ) \qquad ( 1 )$$

$$P = \frac{σ ( {T}_{1}^{4} - {T}_{2}^{4} )}{\frac{1}{ϵ 1} + \frac{1}{ϵ 2} - 1} \qquad ( 2 )$$

$$P = A ( {T}_{1} - {T}_{2} ) \qquad ( 3 )$$

Where P is power load per unit area T1 and T2 are temperature levels, σ is the Stefan Boltzmann constant, ε1 and ε2 is the emissivity of the material of shields, and A is thermal conductivity of the layer shield (W/m2) per unit area

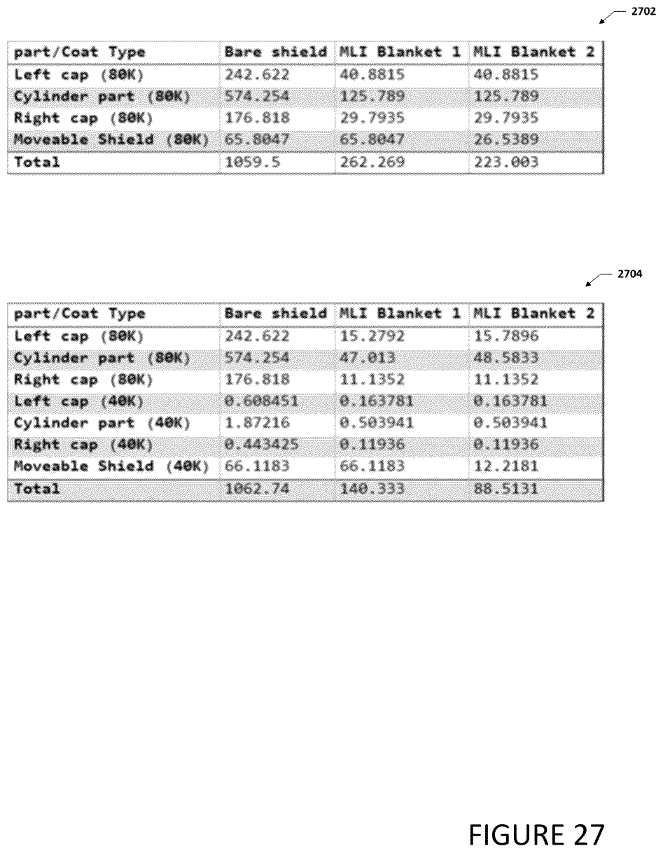

In a baseline configuration where an external eighty (80) K shroud is not present, the anechoic chamber consists of four independent parts: two covers, one of which has a cut out equal to shield area; cylindrical part and moveable cryo shield, which itself has larger construction area but only exposed to three hundred (300) K radiation field of the scanner over geometrical scanning range area of 1200×1200 m2 the Stefan Boltzmann law (Equation (1)) can be used for the caps and shield, and the parallel plate heat transfer equation (Equation (2)) can be used for cylindrical parts taking into account their area. The heat balance calculation result is shown in the table 2702 illustrated in FIG. 27 for different configurations of anechoic chamber and shield coatings.

The bare shield configuration shows a heat balance as is without any multilayer insulation (MLI) blanket applied to either the anechoic chamber or to the moveable cryogenic shield. A cooling power of one (1) kW is required which is achievable by LN cooling circuit but is relatively large when compared to using a multi-layer insultation blanket. By applying multi-layer insultation blanket with A=0.03 in (3) two-hundred and fifty (250) W loads can be achieved on the anechoic chamber which are much more manageable. “MLI blanket 1” configuration considers MLI applied to the shield caps and cylindrical part, while “MLI blanket 2” additionally assumes moveable shield area is also ninety percent (90%) coated with thinner MLI blanket (A=0.06) while ten percent (10%) of the area is left bare (ε1=0.1). Note that for any thermal configuration, the anechoic chamber will always be exposed to a three-hundred (300) K radiation field and will be a single thermal barrier between the three-hundred (300) K environment and the device under test, which is especially important for four (4) K operation.

For a four (4) K configuration, a mathematical model of the multi-layer insulation blanket is created as set of radiative sheets of certain emissivity “ab” which are connected by a parasitic conductance represented by “Ab.” Mathematically this is set of coupled equations which were solved numerically. To choose correct values for “Eb” and “Ab” calculated blanket performance at different temperatures was compared with reference data that was obtained from the manufacturer of the multi-layer insulation blanket. The resulting heat balance is presented in the table 2704 illustrated in FIG. 27.

The anechoic chamber, eighty (80) K shroud, and device under test mounting table can be mounted mechanically independently onto mounting points inside the terahertz testing facility. The mounting legs of each inner element can protrude to the envelope of the outer shield(s) with sufficient clearance to allow for thermal contraction of the shields. Proper heat intercept and heat radiation rejection can be engineered using baffles and flexible heat links around each protrusion point.

In some examples, the anechoic chamber is mounted on a set of four wheel blocks located below the terahertz testing facility. The wheel blocks allow for anechoic chamber movement on top of flat rails, installed at the bottom of the terahertz testing facility. The wheels themselves can be rigidly mounted on the anechoic chamber by a set of M10 stainless steel bolts, through a G10 heat isolating plate or some other similar configuration. This construction has the function of allowing the anechoic chamber to be mounted from the side of the vessel by first attaching it to the crane, then placing the anechoic chamber onto the specially prepared outside frame and subsequently sliding the anechoic chamber inside the terahertz testing facility. Another function of the wheel set is to accommodate thermal expansion and contraction of the anechoic chamber with respect to the thermal vacuum vessel. To prevent the terahertz testing facility from rolling out and to provide reference, the terahertz testing facility can be fixed on to the stiffening ring of the vacuum vessel separating the anechoic chamber and the scanner compartments.

The device under test table can be mounted on its own hexapod arrangement that protrudes through shields as described above. With the symmetrical hexapod arrangement, the position of the canter of the table remains stationary in Z and X direction and only changes height X upon cool down. To access the device under test, the operator must dismount the lid of the thermal vacuum vessel, in the 4 K case, dismount the back plate of the shroud, and dismount the back plate of the anechoic chamber. All covers can be stored on the lids' support structures (see FIG. 1E).

It is to be understood that other embodiments and implementations may be utilized, and structural changes may be made without departing from the scope of the present disclosure. Substantial flexibility is provided by the system and method in that any suitable arrangements and configuration may be provided without departing from the teachings of the present disclosure. For purposes of illustrating certain example techniques of a terahertz testing facility for cryogenic near field beam pattern measurement at terahertz frequencies, the following foundational information may be viewed as a basis from which the present disclosure may be properly explained.

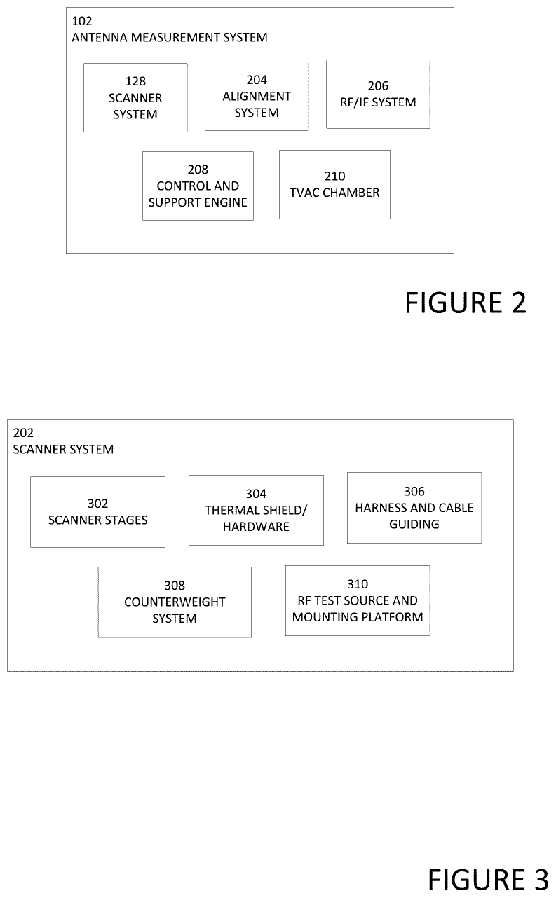

Turning to FIG. 2, FIG. 2 is simplified block diagram of a particular non-limiting example of the terahertz testing facility 102. The terahertz testing facility 102 can include an X,Y,Z-plane scanner system 202, an alignment system 204, a radio frequency/intermediate frequency (RF/IF) system 206, a control and support engine 208, and a terahertz testing facility 210. Turning to FIG. 3, FIG. 3 is a simplified block diagram of a particular non-limiting example of the X,Y,Z-plane scanner system 202. The X,Y,Z-plane scanner system 202 can include scanner stages 302, a thermal shield/hardware 304, a harness and cable guiding 306, a counterweight system 308, and a radio frequency test source and mounting platform 310.

The scanner stages 302 operate at room temperature conditions. The scanner stages can include electrical heaters and thermal sensors at appropriate locations to control the thermal balance and operating temperatures within the system. The thermal shield/hardware 304 can provide a mechanical interface to support a co-moving thermal shield. The harness and cable guiding 306 can provide a cable drag chain to guide the electrical harness between the test source and the external electrical interface. The cable drag chain can help keep the phase-flex radio frequency cables bent at a fixed radius of curvature.

The counterweight system 308 helps to provide a counter weight to move the X,Y,Z-plane scanner system and can be used to help to unload the X,Y,Z-plane scanner system from heavy moveable shield components. A counterweight system similar to the counterweight system 308 can also be used to move other heavy objects related to the terahertz testing facility. The radio frequency test source and mounting platform 310 is a structure on which a radio frequency test source (e.g., the device under test) can be mounted including the auxiliary hardware required to operate the radio frequency test source (e.g., filter boxes, connector brackets, et cetera).

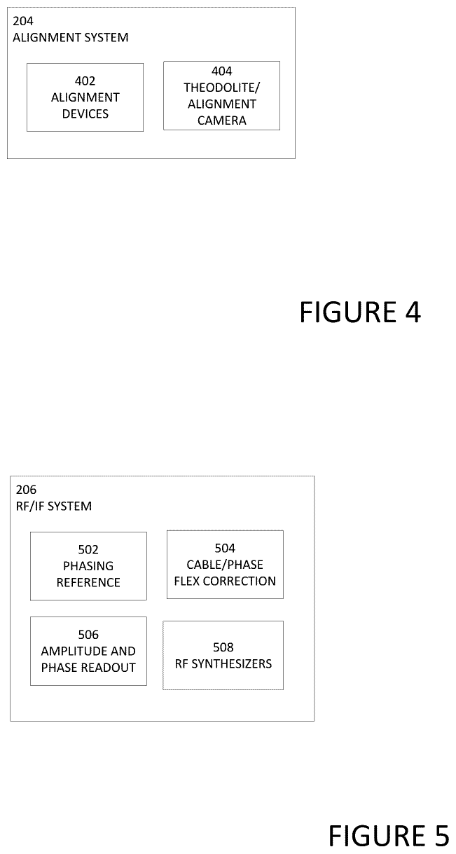

Turning to FIG. 4, FIG. 4 is simplified block diagram of a particular non-limiting example of the alignment system 204. The alignment system 204 can include alignment devices 402 and a theodolite/alignment camera 404. The alignment devices 402 can monitor and control the relative alignment between the SCS and the device under test using alignment devices installed on both the SCS and the device under test. The theodolite/alignment camera 404 helps to establish the relative alignment between the SCS and the device under test. The alignment can be measured using optical equipment (such as a theodolite) outside the TV chamber, or by means of a dedicated alignment camera (internal or external).

Turning to FIG. 5, FIG. 5 is a simplified block diagram of a particular non-limiting example of the radio frequency/intermediate frequency (RF/IF) system 206. The radio frequency/intermediate frequency (RF/IF) system 206 can include a phasing reference 502, a cable/phase flex correction 504, an amplitude and phase readout 506, and radio frequency synthesizers 508. The phasing reference 502 can create a correlated reference from the LO of the device under test and the radio frequency test source.

The cable/phase flex correction 504, can help enable a cable flex phase error monitor by using an out-of-band pilot signal reflected by a low-pass filter at the input of the radio frequency test source. The amplitude and phase readout 506 can be used to help remove correlated phase noise component (e.g., the correlated intermediate frequency detected by the receiver and the IF reference can be combined in an analogue microwave VNA converter network). In this way it is possible to measure with good phase stability and low-phase noise. The radio frequency synthesizers 508 can synthesize radio frequencies.

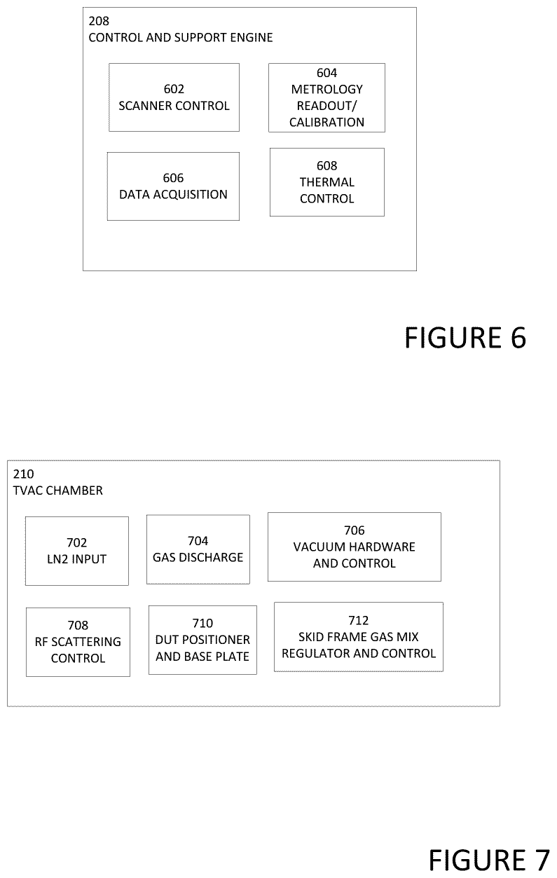

Turning to FIG. 6, FIG. 6 is a simplified block diagram of a particular non-limiting example of the control and support engine 208. The control and support engine 208 can include scanner controls 602, metrology readout/calibration 604, data acquisition 606, and thermal controls 608. The scanner controls 602 is configured to control the motors of the X,Y,Z scanner system. The metrology readout/calibration 604 can help with correction of the position of the radio frequency probe aperture during testing as a function of radio frequency probe position and orientation. At very high frequencies, the scan-plane accuracy cannot be achieved only through physical alignment and control of the machining tolerances. One of the “secondary correction” scenarios for improving the scan plane planarity and the position accuracy is a correction of the position of the radio frequency probe aperture during testing as a function of probe position and orientation.

The data acquisition 606 can be configured to capture and process terahertz signals at cryogenic temperatures to perform and interface with the measurement instruments and record the data for analysis. The thermal controls 608 helps to maintain the temperature of the system and can be a thermo regulation system that distributes and regulates a flow of a liquid/gaseous nitrogen mixture. The thermal design of the system is based on three regulation loops: one electrical heater driven and two mixed phase nitrogen circuits (or three in the 4 K case). A network of heaters and thermometers can be installed on all parts that should be temperature controlled (e.g., the X,Y,Z-scanner (to reach the required position repeatability), the ANEC and the device under test's base/heat exchange plate (to set the temperature of the device under test itself), etc.). A few more thermometers (no heaters) can be installed for diagnostic purposes only. The thermometers can be placed on the device under test, the scavenger plate and on the wall of the vacuum vessel (to detect possible LN2 leaks). All heaters can be controlled individually. Hence, the approach is to use nitrogen cooling to reach some base temperature (a few K below the desired operating temperatures), and to use the heaters to maintain the desired temperature distributions.

Turning to FIG. 7, FIG. 7 is a simplified block diagram of a particular non-limiting example of the terahertz testing facility 210. The terahertz testing facility 210 can include a LN2 input 702, gas discharge 704, vacuum hardware and control 706, radio frequency scatting control 708, device under test positioner and base plate 710, and side frame gas mix regulator and control 712. The LN2 input 702 helps to regulate and distribute the quid nitrogen supply, gas nitrogen supply, exit heater, and heat exchanger. For example, peak power consumption as well as liquid nitrogen consumption for entire full system which, depending on configuration may include three circuits. These circuit can share common liquid nitrogen supply, gas nitrogen supply, exit heater and heat exchanger, but can have their own gas heaters, mixing chambers and associate switching valves.

The gas discharge 704 helps to regulate the discharge of gas from the system. The main gas discharge may happen through exit gas heater and external heat exchanger, to prevent discharge of liquid nitrogen. An electropneumatic normally closed gate valve can be used. If the power is suddenly interrupted, the gate valve can switch to its closed position to prevent the system from flooding with air while cold.

The vacuum hardware and control 706 helps to control the pumps that create a vacuum in the terahertz testing facility and regulate the created vacuum. In a specific example, the vacuum system contains a turbomolecular pump T1 including a backing pump (“Scroll pump”), a high-capacity roots/fore pump combination (roughing pump), and pressure monitors S1, S2 both in the vacuum chamber and at the exit of the turbopump.

The radio frequency scatting control 708 helps to absorb electromagnet waves in the terahertz testing facility. Creating efficient absorption of electromagnetic waves is a challenging task because many absorbing materials become less efficient at cryogenic temperatures. The requirement for a good absorption coefficient in the band(s) of the device measurement is S11<−30 dB, to counteract both diffuse and specular reflections. As an example, a silicon carbide (SiC) grain loaded STYCAST coating (and not only) deposited on an aluminium plate surface in vacuum and cryogenic conditions is used.

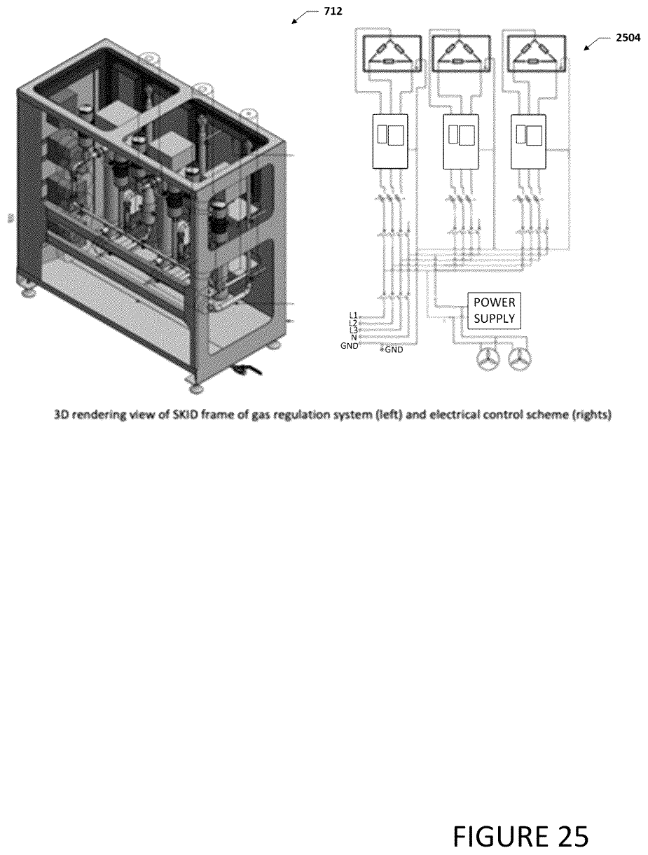

The device under test positioner and base plate 710 is a rotating platform mounted on a base plate with an azimuthal positioner that allows for the rotation of the device under test around the gravity vector, to allow testing across- and along-track ranges without breaking the vacuum. The base plate is cooled from below by an independent mixed nitrogen circuit. The side frame gas mix regulator and control 712 is illustrated in FIG. 25.

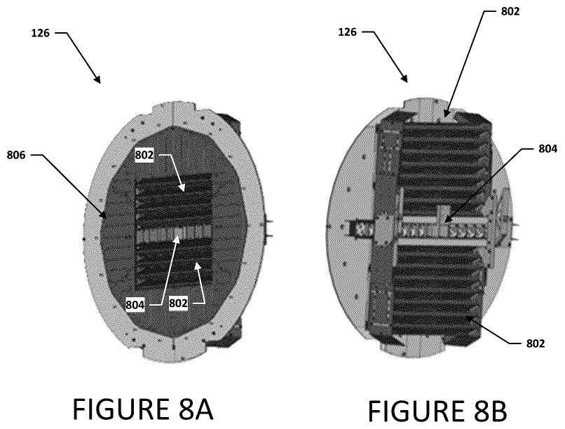

Turning to FIGS. 8A and 8B, FIGS. 8A and 8B are a simplified block diagram of a particular non-limiting example of the thermal/radiation shield 126. FIG. 8A is illustrates the side of the thermal/radiation shield 126 that faces the X,Y,Z-plane scanner system (not shown) and FIG. 8B illustrates the side of the thermal/radiation shield 126 that faces the device under test. The thermal/radiation shield 126 can include pleated blinds 802 and a testing aperture 804. The inside (e.g., a first side) of the thermal/radiation shield 126 can be coated by absorber material 806 and the outside (e.g., a second side) of the thermal/radiation shield 126 by multilayer insulation (not shown). The absorber material 806 is used to minimize reflections of electromagnetic waves and the absorber material 806 can include Stycast/SiC, carbon loaded materials, multilayer dielectric and/or some other material, depending on the specific frequency range and performance requirements.

The pleated blinds 802 of thermal/radiation shield 126 are configured to function much like an accordion/pleated blinds, but in two dimensions. The testing aperture 804 moves with the test source and the thermal/radiation shield 126 can be attached to and move with the X,Y,Z-plane scanner system 128 (not shown).

The system can include a moveable heat barrier between the anechoic chamber that includes the device under test and the X,Y,Z-plane scanner system such that a radio frequency test probe can be moved around in a 1000×1000 mm field, while the cryogenic environment of the anechoic chamber is not compromised. Hence, the thermal/radiation shield 126 can be cooled conductively, the discussed structure is placed within the lid of the anechoic chamber. The inside part (the side that is facing the device under test) can be coated with anti-reflection coating while the outside part (the side that is facing the X,Y,Z-plane scanner system 128) can be covered by multi-layer insulation blankets to keep the heat out.

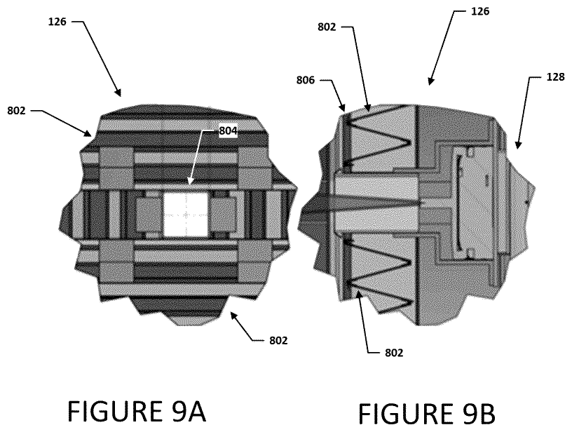

Turning to FIGS. 9A and 9B, FIGS. 9A and 9B are a simplified block diagram of a particular non-limiting example of the thermal/radiation shield 126. FIG. 9A illustrates the side of the thermal/radiation shield 126 that faces the device under test and FIG. 9B illustrates a side cut away view of the thermal/radiation shield 126. The thermal/radiation shield 126 can include the pleated blinds 802 and the testing aperture 804. The inside of the thermal/radiation shield 126 can be coated by the absorber material 806 and the outside by multilayer insulation (not shown). The testing aperture 804 can move with the test source and the thermal/radiation shield 126 can be attached to and move with the X,Y,Z-plane scanner system 128.

The harmonic design of the thermal/radiation shield 126 is chosen not only because it is relatively easy to manufacture and operate, but also its surface normals do not point towards the receiver of the X,Y,Z-plane scanner system to reflect waves, signals, electromagnetic interference, etc. away from the X,Y,Z-plane scanner system to help alleviate risk of reflections distorting beam pattern measurements. The pleated blinds 802 are overlapping (big, small, big, small, etc.) on the side of the thermal/radiation shield 126 that faces the device under test. It is important to note that the angle between two neighboring pleated blinds 802 should not exceeds ninety degrees (90°) and may be as small as fourteen degrees (14°). The response to electromagnetic radiation by the thermal/radiation shield 126 might become very polarization dependent because the pleated blinds 802 form a vertical grid that reflects vertically polarized light much more than it reflects horizontally polarized light. To mitigate this problem, on the side of the thermal/radiation shield 126 that is facing the device under test, the pleated blinds 802 near the end of the thermal/radiation shield 126 may be bent to mitigate the response to electromagnetic radiation.

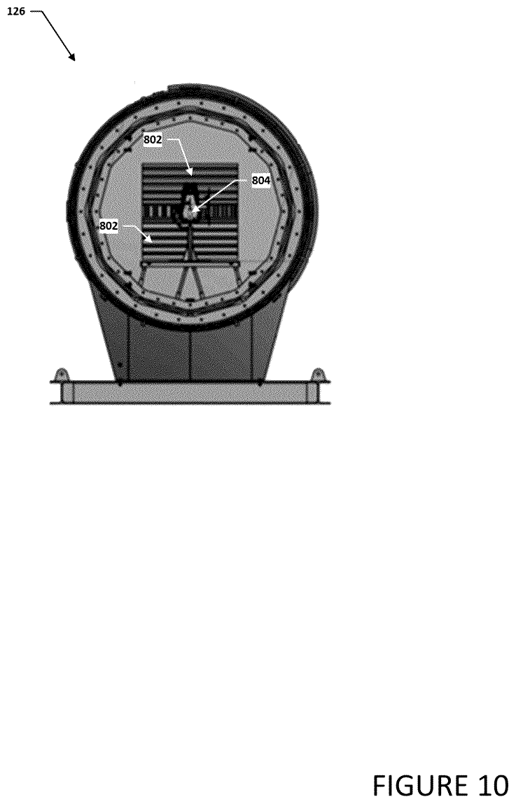

Turning to FIG. 10, FIG. 10 is a simplified block diagram of a particular non-limiting example of the thermal/radiation shield 126. FIG. 10 is illustrating the thermal/radiation shield 126 as seen from the perspective of the device under test (not shown). The thermal/radiation shield 126 can include the pleated blinds 802 and the testing aperture 804. The pleated blinds 802 of thermal/radiation shield 126 are configured to function much like an accordion/pleated blinds, but in two dimensions. The testing aperture 804 moves with the test source and the thermal/radiation shield 126 can be attached to and move with the X,Y,Z-plane scanner system 128 (not referenced).

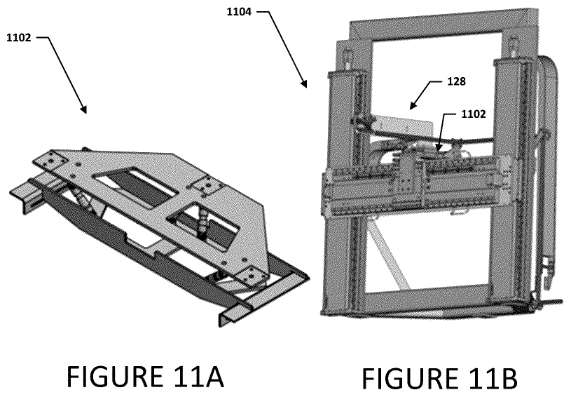

Turning to FIGS. 11A and 11B, FIGS. 11A and 11B are a simplified block diagram of a particular non-limiting example of a hexapod support structure 1102 to support the X,Y,Z-plane scanner system 128 (illustrated in FIG. 11B). FIG. 11A illustrates the hexapod support structure 1102 and FIG. 11B illustrates the hexapod support structure 1102 attached to the X,Y,Z-plane scanner system 128 in a scanner system frame 1104. The hexapod support structure 1102 can be similar to a Stewart platform.

A Stewart platform is a type of parallel manipulator that has six prismatic actuators, commonly hydraulic jacks or electric linear actuators, attached in pairs to three positions on the platform's baseplate, crossing over to three mounting points on a top plate. All connections the hexapod support structure 1102 can be made via universal joints. Devices placed on the top plate can be moved in six degrees of freedom; three linear movements x, y, z (lateral, longitudinal, and vertical), and three rotations (pitch, roll, and yaw). By loosening/tightening the bolts, the hexapod support structure 1102 can be used to adjust the orientation of the X,Y,Z-plane scanner system 128 in all six spatial degrees of freedom.

However, the main goal of the hexapod support structure 1102 is to minimize the amount of deformations under loading that can occur, in particular when cycling between atmospheric pressure and vacuum. Because of the hexapod structure of the hexapod support structure 1102, the scanner plane of the X,Y,Z-plane scanner system 128 can move somewhat, but should not bend. The X,Y,Z-plane scanner system 128 can be unbolted from/bolted on the hexapod support structure 1102. It is also possible to dismount the whole X,Y,Z-plane scanner system 128 and the hexapod support structure 1102 together as one unit or system.

The scanner system frame 1104 can include a Linear Variable Differential Transformers (LVDT) position measurements system. The Linear Variable Differential Transformers (LVDT) position measurements system in the scanner system frame 1104 can measure position and tilts of the scanner system frame 1104 as a whole.

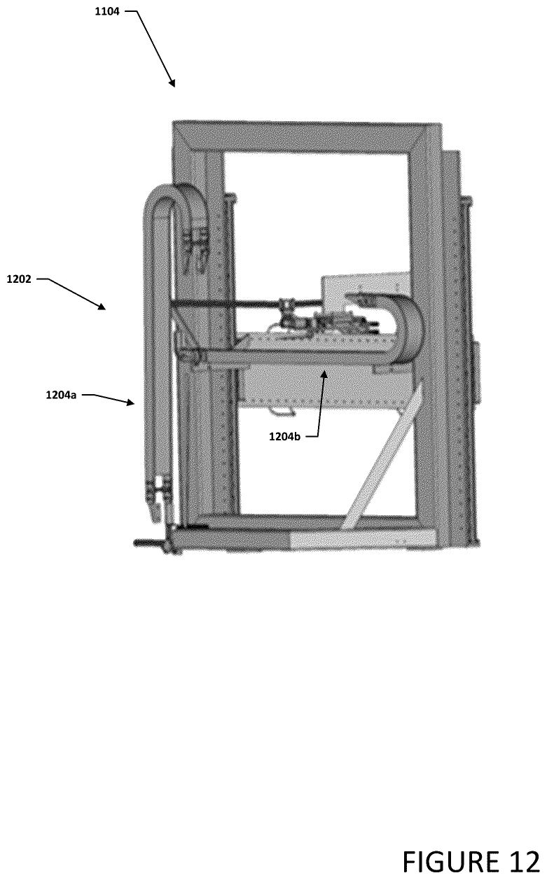

Turning to FIG. 12, FIG. 12 is a simplified block diagram of a particular non-limiting example of the scanner system frame 1104 with an example cable harness and cable tray layout 1202. The cable harness and cable tray layout 1202 can help guide radio frequency cables, cables for power supply and digital control, heater cables, temperature sensor cables, scanner position/control system signals, and other cables used by the system. A stable bending radius can be ensured by using two perpendicular cable trays 1204a and 1204b as shown in FIG. 12. In a specific example, bending radius of open-hundred (100) mm is possible for given scanner dimensions. The cable harness and cable tray layout 1202 can also help maintain a fixed cable length without additional stress or change in cable bending angles.

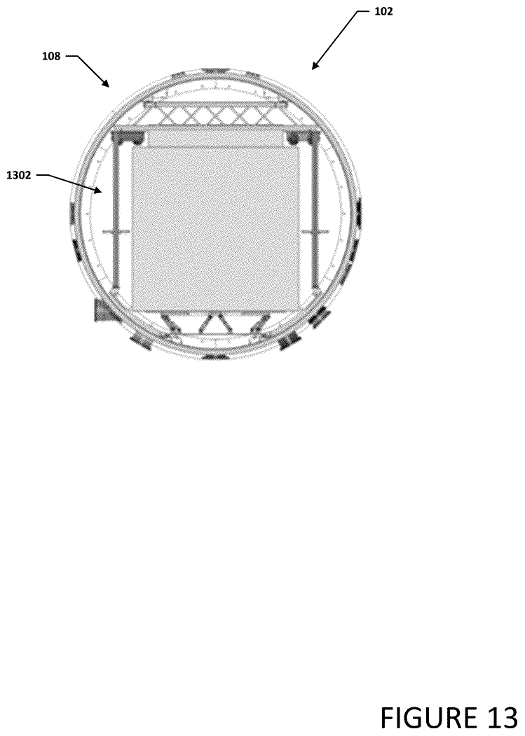

Turning to FIG. 13, FIG. 13 is a simplified block diagram of a particular non-limiting example of a counter weight system 1302 that can be used inside the main body 108 of the terahertz testing facility 102. Note that in FIG. 13, the area in the middle of the Figure represents the thermal/radiation shield 126 (not shown) and the X,Y,Z-plane scanner system 128 (not shown). The counter weight system 1302 can be used to load and unload the X,Y,Z-plane scanner system 128 from the main body 108 of the terahertz testing facility 102.

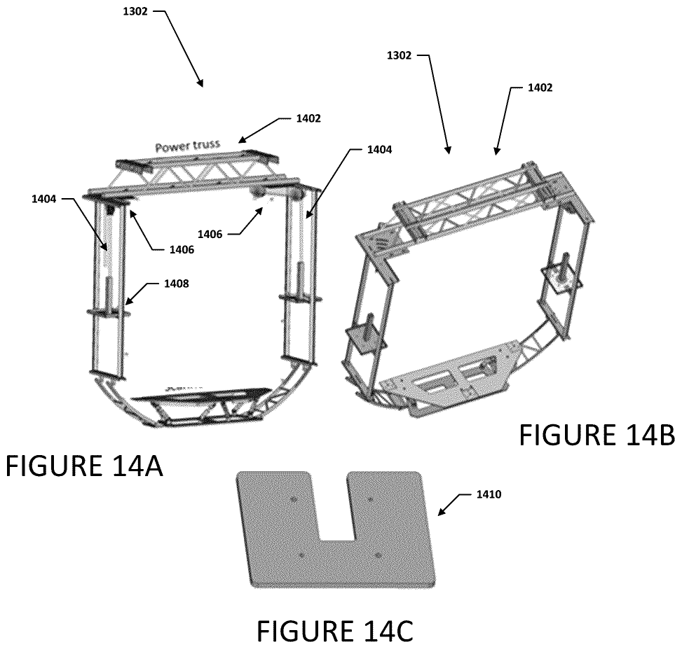

Turning to FIGS. 14A-14C, FIGS. 14A-14C are a simplified block diagrams of a particular non-limiting example of the counter weight system 1302. Due to strengthening measures (parallel pantograph truss reinforcement), heavier anti-reflective coating and heavier copper heat straps for the thermal/radiation shield 126 (not shown) the mass of the thermal/radiation shield 126 that needs to be moved vertically can exceed two-hundred (200) kg. This weight exceeds the maximum that a double Y-stage gantry could carry. To allow for movement of the thermal/radiation shield 126, the counter weight system 1302 can be configured to unload the at least a portion of the forces on the X,Y,Z-plane scanner system 128 (not shown) in the y-direction and present manageable static load through the whole range of displacement of the thermal/radiation shield 126.

The counter weight system 1302 consists of the power truss 1402. The power truss 1402 can be attached to a top rail mount of the terahertz testing facility 102 using attachment brackets. The rails in the terahertz testing facility 102 can have slots machined in the direction along the cylindrical axis of the main body 108 of the terahertz testing facility 102. The slots can be utilized to move the whole counterweight system and to finely adjust the orientation of the ropes 1404 (e.g., 6 mm thick wire ropes) that are attached to a central part of the thermal/radiation shield 126. The line between attachment points of the ropes 1404 are located just above the center of mass of the central part of the thermal/radiation shield 126 with attached vertical parts of the thermal/radiation shield 126.

The counter weight action is carried out by means of two sets of ropes 1404 threaded through dual roller blocks 1406. A first end of the ropes 1404 can be attached to the one or more weight platforms 1408. Weights 1410 can be added to the one or more weight platforms 1408 to help counter balance the X,Y,Z-plane scanner system 128. An opposite second end of the ropes 1404 is attached to a central part of the thermal/radiation shield 126 (not shown). The dual roller blocks 1406 allow for the placement of the one or more weight platforms 1408 sufficiently away from the central part of the thermal/radiation shield 126 while allowing for vertical displacement (e.g., one (1) m linear vertical displacement). The dual roller blocks 1406 can have three groves to be able to place up to three parallel ropes 1404

In another example, instead of the counter weight system 1302, to allow for movement of the thermal/radiation shield 126, an externally actuated moveable shield could be used. However, the externally actuated moveable shield would involve an extra set of vacuum compatible motors that actuate the shield independently from the main Y-axis of the X,Y,Z-plane scanner system 128 (not shown).

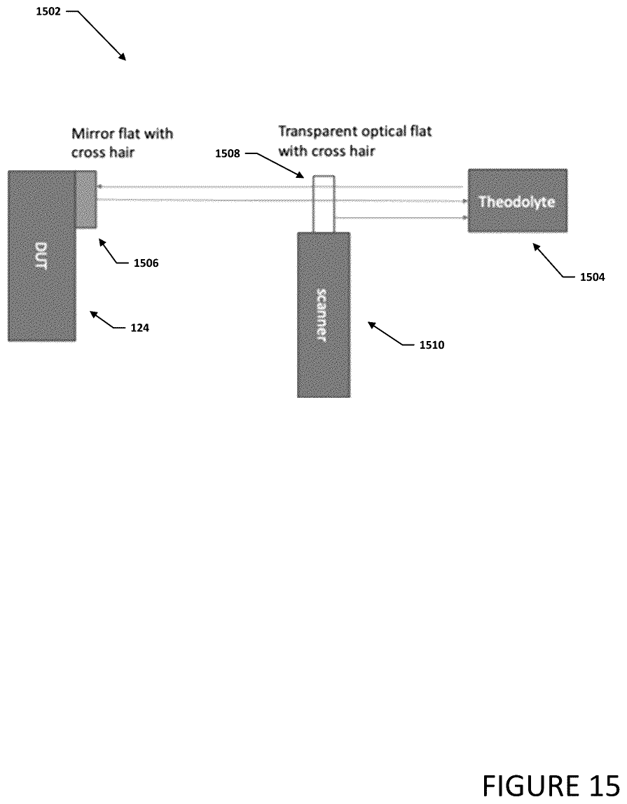

Turning to FIG. 15, FIG. 15 is a simplified block diagram of a particular non-limiting example of an alignment system 1502. The alignment system 1502 can be an auto collimation scheme using a theodolite 1504 for determining relative angles and aligning a cross-hair image on an alignment device mounted both on the scanner and on the device under test. The theodolite 1504 is a precision instrument used for measuring angles both horizontally and vertically. Theodolites can rotate along their horizontal axis as well as their vertical axis.

In an illustrative non-limiting example, the alignment system 1502 illustrated in FIG. 15 is a single port alignment system. Generally, the alignment system 1502 includes alignment devices (e.g., several pentaprizms and flat mirrors) that are mounted on the different parts of X,Y,Z stage. The alignment system 1502 is illuminated from a theodolite/laser beam through a vacuum compatible optical illuminator window.

An aluminized first optical flat glass 1506 with cross hair is mounted on the device under test 124 and aligned with its mechanical reference plane and position. Another second optical flat glass 1508 with cross hair is mounted onto a scanner 1510 and aligned with the scan plane using dedicated procedure. The cross-hair position of the second optical flat glass 1508 is referred to position of the center of radiator horn (or any reference position) by moving the scanner 1510, such that relative position of cross hair is known within the mechanical accuracy of the scanner 1510. This allows to accurately position the cross hair of the first optical flat glass 1506 on the device under test 124 with respect to the scanner 1510 and also scanning plane angles with respect to the device under test 124 coordinate reference. With knowing the distance between alignment devices on the device under test 124 and the scanner 1510, it is possible to reconstruct the actual position of cross in device under test in scanner coordinate system.

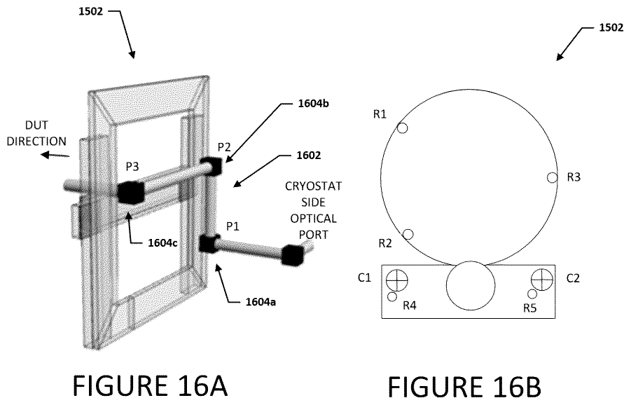

Turning to FIGS. 16A and 16B, FIGS. 16A and 16B are simplified block diagrams of a particular non-limiting example of an alignment system 1502. The alignment system 1502 can be readily utilized to align the device under test 124 and the X,Y,Z-plane scanner system 128. More specifically, a beam from an optical port 1602 is reflected by three pentaprisms 1604a, 1604b, and 1604c and directed towards the second optical flat glass 1508 with cross hair is mounted onto the scanner 1510. The optical configuration helps to ensure that the beam in direction of the device under test 124 is moving with the scanner 1510 in the X-Y position but always stays in the same direction as a property of the three pentaprisms 1604a, 1604b, and 1604c (the pentaprism is a five-sided reflecting prism used to deviate a beam of light by a constant ninety degrees (90°)). More specifically, the first pentaprism 1604a is mounted on an X-stage and is stationary all the time. The second pentaprism 1604b is mounted onto a Y stage and moves only in the Y direction. The third pentaprism 1604c is mounted onto an X-stage and moves in the X and Y direction. This arrangement allows the alignment system 1502 to view any alignment device mounted on the device under test 124 that is within scanning range. The beam is further relayed by set of fixed mirrors to the optical port on the side of terahertz testing facility 102.

The alignment system 1502 allows to relate the X and Y planes relative to the device under test 124 and two angles of the target on the device under test 124 to the X and Y planes relative to the scanner coordinate system associated with the scanner 1510. In order to relate distance along the Z-axis, laser ranging may be used. To relate distance along the Z-axis, two retroreflectors may be mounted, one near the reticle on the scanner and another near reflecting alignment device on the device under test. The distance to both devices can be determined by irradiating them through an optical port and differential distance defines scanner Z position in a coordinate system for the device under test. This implies that an optical port vacuum window is tilted with respect to beam axis to reduce retroreflector.

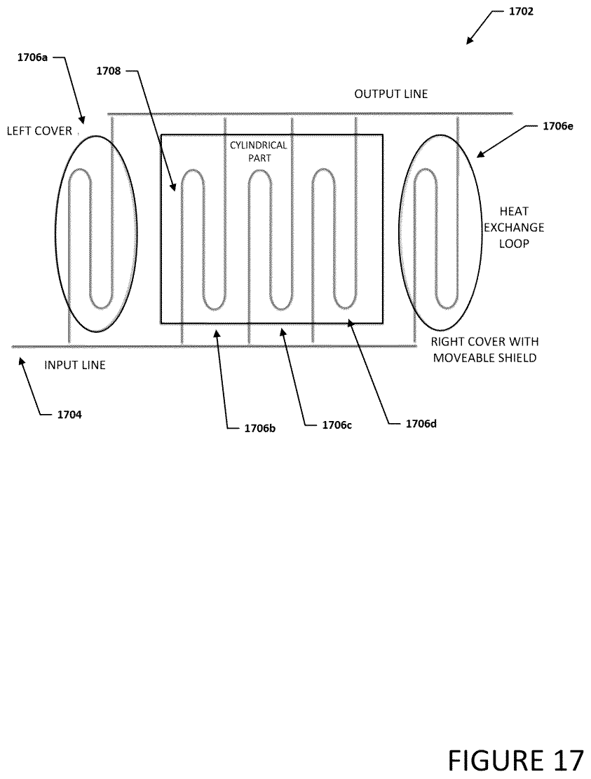

Turning to FIG. 17, FIG. 17 is a simplified block diagram of a particular non-limiting example of a shroud cooling layout 1702. The shroud cooling layout 1702 includes a cooling gas/liquid supply line 1704. The cooling gas/liquid supply line 1704 is located on the bottom of the shroud cooling layout 1702 illustrated in FIG. 17. Cooling commences through loops 1706 of tubes 1708. In some examples, the loops 1706 can be made out 10 mm diameter copper tubes 1708. If there are five (5) loops 1706, three (3) loops 1706b-1706d can be brazed to cylindrical part of the shroud and one (1) loop 1706a can be brazed to the first lid shroud 130 and one (1) loop 1706e can be brazed to the shield shroud 134. In a specific example, a distance between tubes can be one hundred (100) mm to help ensure uniform temperature distribution. In some examples, the length of each loop 1760a-1760e should be the same. Each loop 1760a-1760e cools approximately the same area of the shroud to help enable good heat balance at steady state operation. The cooling power for each loop 1760a-1760e is similar with exception to the loop 176e in the shield shroud 134 on the thermal/radiation shield 126, because the thermal/radiation shield 126 can cool down slower than the rest of the shroud and will determine the cool down time of the system due to its RC constant.

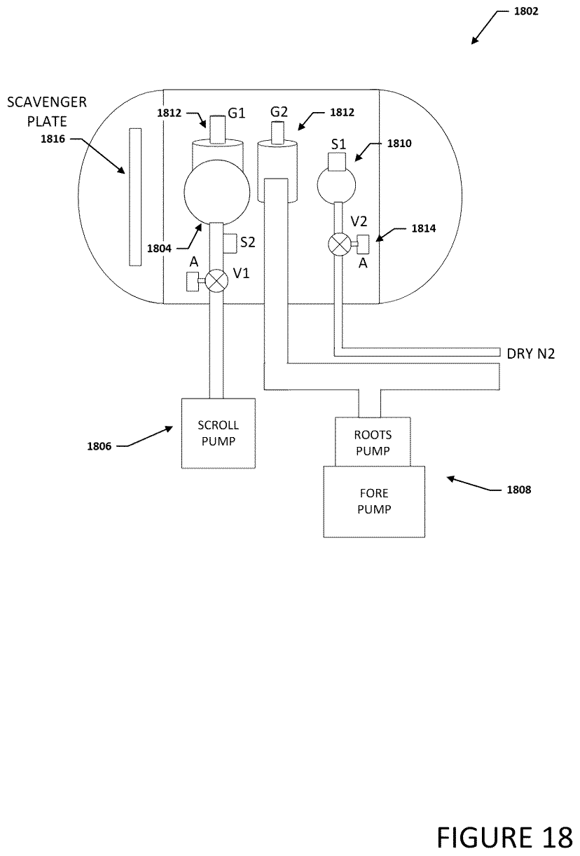

Turning to FIG. 18, FIG. 18 is a simplified block diagram of a particular non-limiting example of a vacuum system layout 1802. The vacuum system layout 1802 is located in the main body 108 of the terahertz testing facility 102. More specifically, the vacuum system layout 1802 is located in the anechoic chamber 120 portion of the main body 108. The vacuum system layout 1802 includes a turbomolecular pump T1 1804 including a scroll pump 1806 (turbopump, backing pump), a high-capacity roots/fore pump combination (roughing pump) 1808, and one or more pressure monitors 1810 (FIG. 18 shows two pressure monitors, S1, S2, both in the vacuum chamber and at the exit of the turbopump). The roots/fore pump combination 1808 will be shared with a neighboring solar simulator (not shown) as it is only required for a limited time by both. The scroll pump 1806 and the roots/fore pump combination 1808 are connected through gate valves 1812. For example, the gate valves 1812 are illustrated G1 and G2 in FIG. 18 and can include fitting ISO F-250 and ISO F-160 flanges respectively. The system can be vented by dry nitrogen gas through a proportional valve 1814. The vacuum system layout 1802 can also be equipped with a scavenger panel 1816 which runs at liquid nitrogen level and allows to pump on any contamination outgas as well as water. In some examples, the vacuum system layout 1802 can include a contamination monitor (not shown).

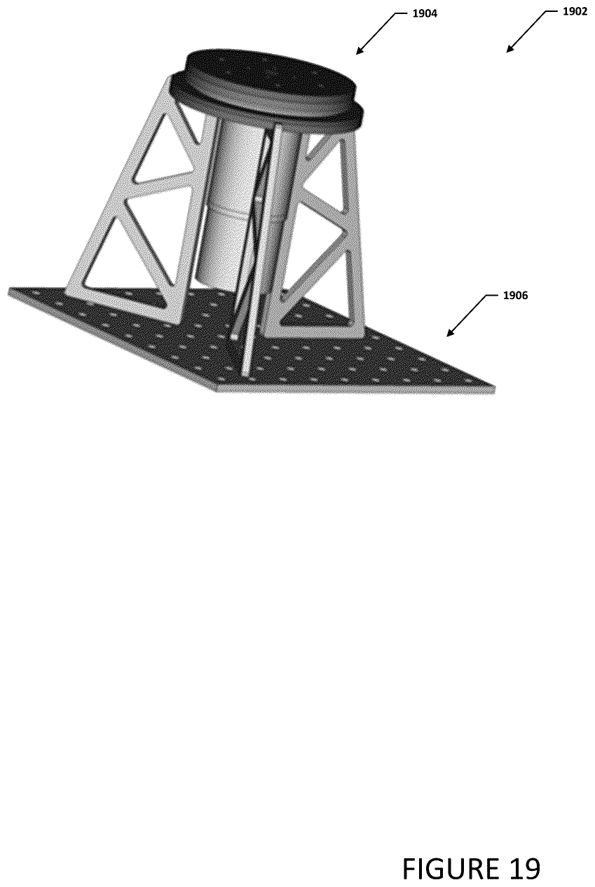

Turning to FIG. 19, FIG. 19 is a simplified block diagram of a particular non-limiting example of a device under test platform 1902. The device under test platform 1902 is a rotating platform 1904 mounted on a base plate 1906. The device under test platform 1902 also includes an azimuthal positioner (not referenced) that allows the device under test 124 (not shown) to rotate around a gravity vector. The device under test platform 1902 also allows testing the device under test 124 with across and along-track ranges without breaking the vacuum in the in the anechoic chamber 120 portion of the main body 108 of the terahertz testing facility 102. The rotating platform 1904 is driven by stepper motors (not shown), which are vacuum and cryogenically compatible. Outgassing holes in a rear flange of the rotating platform 1904 can allow for rapid evacuation and purging of the motors to make sure that no gas inclusions may occur.

In a specific example, the base plate 1906 contains a regular grid of 42 M12 holes (ISO metric screw threads), spaced 200 mm apart. In some examples, the base plate 1906 is cooled by an independent mixed nitrogen circuit. In a specific implementation, the independent mixed nitrogen circuit is on a side of the base plate 1906 that is opposite the side that includes the rotating platform 1904. Also, in some examples, the base plate 1906 (not the rest of the anechoic chamber 120) is cooled to four (4) K. In other examples, the base plate 1906 and the anechoic chamber 120 are cooled to four (4) K.

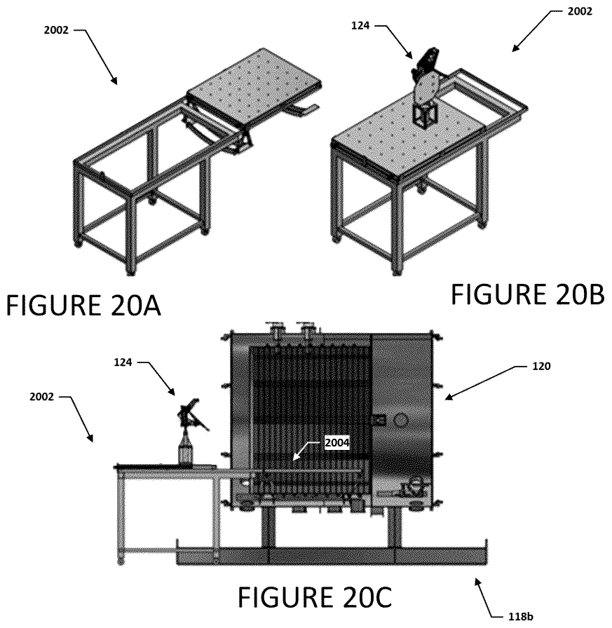

Turning to FIGS. 20A-20C, FIGS. 20A-20C are simplified block diagrams of a particular non-limiting example of a base plate cart 2002. The base plate cart 2002 can help insert and remove the device under test 124 from the anechoic chamber 120. More specifically, to reach the device under test 124 (illustrated in FIGS. 20B and 20C), which can be located up to two (2) meters inside the anechoic chamber 120, a frame 2004 (illustrated in FIG. 20C) can be used to slide the base plate 1906 in and out the anechoic chamber 120. The base plate 1906 can be thermally connected to the anechoic chamber 120. As a result, the base plate 1906 will have the same temperature as the rest of the anechoic chamber 120. The base plate cart 2002 has the correct height and the exact same frame 2004 mounted on top of base plate cart 2002 to allow the base plate 1906, rotating platform 1904, and the device under test 124 to be inserted and removed from the anechoic chamber 120.

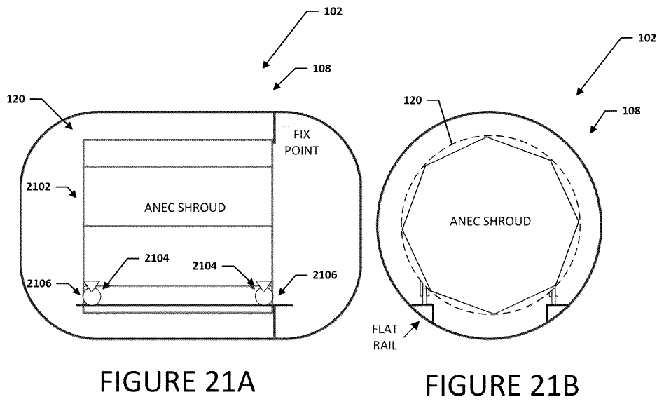

Turning to FIGS. 21A and 21B, FIGS. 21A and 21B are simplified block diagrams of a particular non-limiting example of a device under test mounting table 2102 in the anechoic chamber 120 of the main body 108 of the terahertz testing facility 102. The anechoic chamber 120, the first chamber main body shroud 132, and the device under test mounting table 2102 can be mounted mechanically independently onto mounting points inside the terahertz testing facility 102. The mounting legs of each inner element can protrude to the envelope of the outer shield(s) with sufficient clearance to allow for thermal contraction of the shields. Proper heat intercept and heat radiation rejection can be engineered using baffles and flexible heat links around each protrusion point.

In some examples, the anechoic chamber 120 is mounted on the set of four-wheel blocks 2104 located in the terahertz testing facility 102. The wheel blocks 2104 allow for movement of the anechoic chamber 120 on top of flat rails, installed at the bottom of the terahertz testing facility 102. In a specific example, the wheels 2106 themselves are rigidly mounted on the anechoic chamber 120 by a set of M10 stainless steel bolts, through a G10 heat isolating plate (not shown). This construction has the function of allowing the anechoic chamber 120 to be mounted from the side of the terahertz testing facility 102 by first attaching it to the crane, then placing the anechoic chamber 120 onto the device under test mounting table 2102 and subsequently sliding the anechoic chamber 120 inside the terahertz testing facility 102. Another function of the wheels 2106 is to accommodate thermal expansion and contraction of the anechoic chamber 120 with respect to the terahertz testing facility 102. Upon cooling down the physical dimensions of the terahertz testing facility 102 can change up to half a cm in length and diameter. The longitudinal change is accommodated by rolling action of the wheels 2106 and the transversal change is accommodated by sliding of the wheel 2106 on top of the flat rail surface.

The device under test mounting table 2102 can be mounted on its own hexapod arrangement that protrudes through shields as described above. With the symmetrical hexapod arrangement, the position of the canter of device under test mounting table 2102 remains stationary in Z and X direction and only changes height X upon cool down.

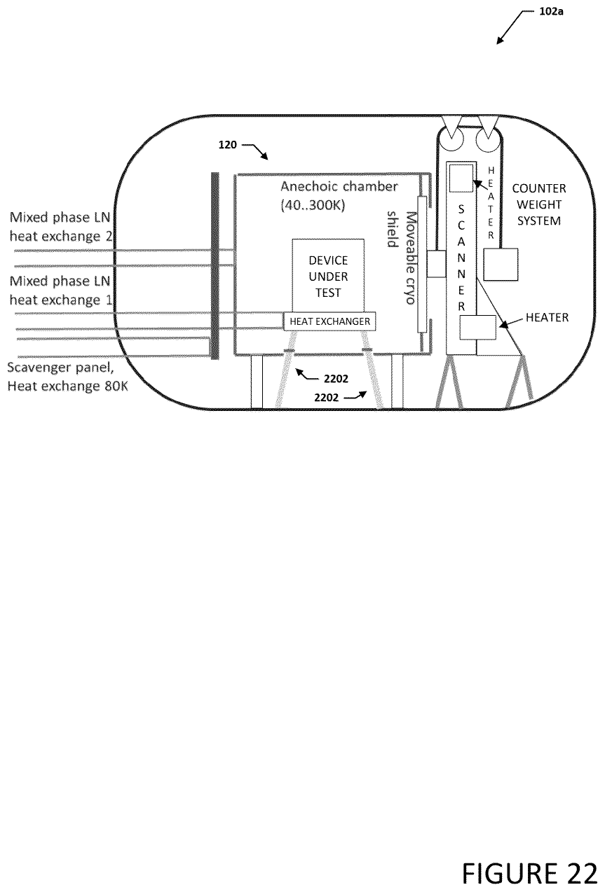

Turning to FIG. 22, FIG. 22 is a simplified block diagram of a particular non-limiting example of a terahertz testing facility 102a. In an example, the anechoic chamber 120 is placed into the terahertz testing facility 102a and is supported by heat isolating material support legs 2202). The anechoic chamber 120 is made from aluminium alloy and polished, or some other material, to reduce emissivity to the level of approximately 0.05. The inside of the anechoic chamber 120 it is coated by Stycast/SiC grains anti-reflection coating or some other coating and has an emissivity very close to unity. Cooling is achieved by a mixed phase liquid/gas Nitrogen circuit (e.g., illustrated in FIG. 17), wrapped around the cylinder of the terahertz testing facility 102a. The anechoic chamber 120 is shielded by the thermal/radiation shield 126 which is attached to the X,Y,Z-plane scanner system 128 or has its own motorized stage. The purpose of the thermal/radiation shield 126 to provide no reflection or minimal reflection from the device under test 124 at submm wavelengths, provide thermal isolation environment and at the same time provide access to a radio frequency probe mounted on the X,Y,Z-plane scanner system 128 for measurement of beam pattern. The side of the thermal/radiation shield 126 that is facing the device under test 124 can be covered by absorbing material (Stycast/SiC) and the opposite side of the thermal/radiation shield 126 that is facing the X,Y,Z-plane scanner system 128 can be polished to reduce emissivity.

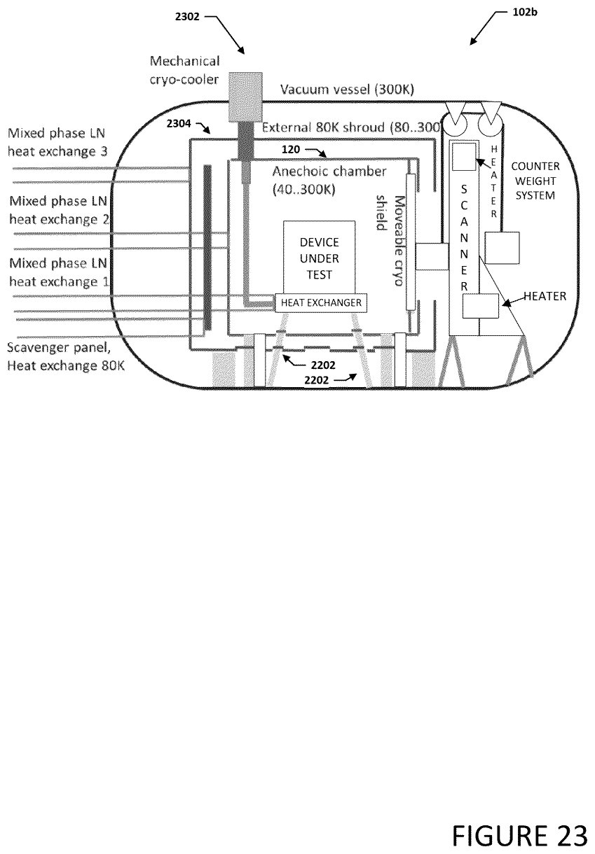

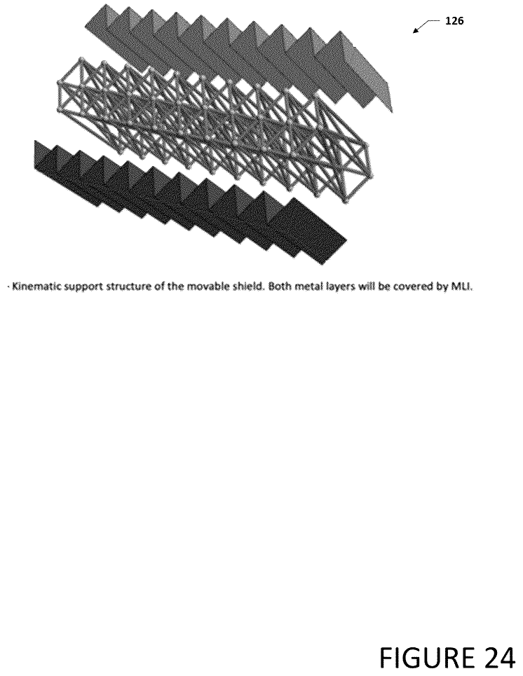

Turning to FIG. 23, FIG. 23 is a simplified block diagram of a particular non-limiting example of a terahertz testing facility 102b. In some examples, to operate the device under test 124 at about four (4) K, a mechanical cryocooler 2302 can be used. In addition, an external shroud 2304 can be over the anechoic chamber 120 may be used. Depending on radiation properties of the device under test 124, the mechanical cryocooler 2302 alone may not be enough to reach four (4) K and an additional shroud between the anechoic chamber 120 and the device under test 124 is required for the 4K system.

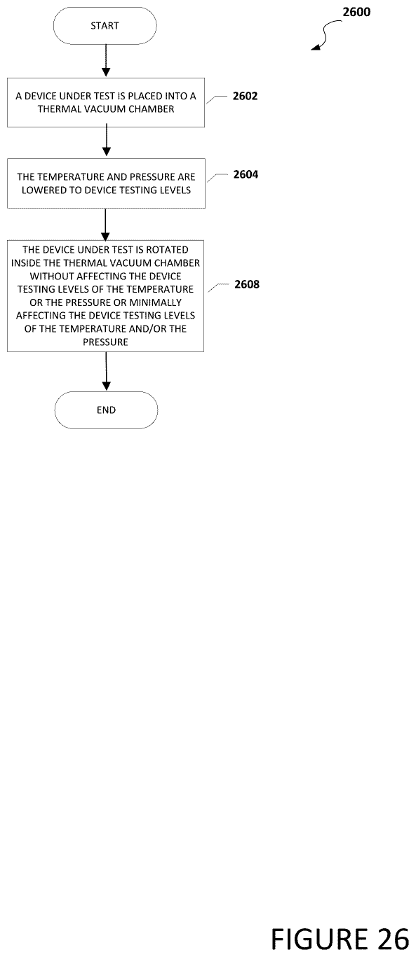

Turning to FIG. 26, FIG. 26 is example flowchart illustrating possible operations of a flow 2600 that may be associated with a system, an apparatus, and a method to help enable a terahertz testing facility for cryogenic near field beam pattern measurement at terahertz frequencies. At 2602, a device under test is placed into a terahertz testing facility. At 2604, the temperature and pressure are lowered to device testing levels. At 2606, the device under test is rotated inside the terahertz testing facility without affecting the device testing levels of the temperature or the pressure or only minimally affecting the device testing levels of the temperature and/or the pressure.

In the description, various aspects of the illustrative implementations are described using terms commonly employed by those skilled in the art to convey the substance of their work to others skilled in the art. However, it will be apparent to those skilled in the art that the embodiments disclosed herein may be practiced with only some of the described aspects. For purposes of explanation, specific numbers, materials, and configurations are set forth in order to provide a thorough understanding of the illustrative implementations. However, it will be apparent to one skilled in the art that the embodiments disclosed herein may be practiced without the specific details. In other instances, well-known features are omitted or simplified in order not to obscure the illustrative implementations.

In the detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense. For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). Reference to “one embodiment” or “an embodiment” in the present disclosure means that a particular feature, structure, or characteristic described in connection with the embodiment is included in at least one embodiment. The appearances of the phrase “in one embodiment” or “in an embodiment” are not necessarily all referring to the same embodiment. Reference to “one example” or “an example” in the present disclosure means that a particular feature, structure, or characteristic described in connection with the embodiment is included in at least one example or embodiment. The appearances of the phrase “in one example” or “in an example” are not necessarily all referring to the same examples or embodiments. The terms “substantially,” “close,” “approximately,” “near,” and “about,” generally refer to being within +/−20% of a target value based on the context of a particular value as described herein or as known in the art. Similarly, terms indicating orientation of various elements (e.g., “coplanar,” “perpendicular,” “orthogonal,” “parallel,” or any other angle between the elements) generally refer to being within +/−20% of a target value based on the context of a particular value as described herein or as known in the art.

As used herein, the term “when” may be used to indicate the temporal nature of an event. For example, the phrase “event ‘A’ occurs when event ‘B’ occurs” is to be interpreted to mean that event A may occur before, during, or after the occurrence of event B, but is nonetheless associated with the occurrence of event B. For example, event A occurs when event B occurs if event A occurs in response to the occurrence of event B or in response to a signal indicating that event B has occurred, is occurring, or will occur. Substantial flexibility is provided by the terahertz testing facility 102 and the system and method to help enable the thermal vacuum chamber for cryogenic near field beam pattern measurement at terahertz frequencies in that any suitable arrangements, chronologies, configurations, and timing mechanisms may be provided without departing from the teachings of the present disclosure.

Note that with the examples provided herein, interaction may be described in terms of one, two, three, or more elements. However, this has been done for purposes of clarity and example only. In certain cases, it may be easier to describe one or more of the functionalities by only referencing a limited number of elements. It should be appreciated that the terahertz testing facility and its teachings are readily scalable and can accommodate a large number of components, as well as more complicated/sophisticated arrangements and configurations. Accordingly, the examples provided should not limit the scope or inhibit the broad teachings of the terahertz testing facility and the system and method to help enable the terahertz testing facility as potentially applied to a myriad of other architectures.

It is also important to note that the operations in the preceding flow diagram (i.e., FIG. 26) illustrate only some of the possible correlating scenarios and patterns that may be executed, some of these operations may be deleted or removed where appropriate, or these operations may be modified or changed considerably without departing from the scope of the present disclosure. In addition, the timing of these operations may be altered considerably. The preceding operational flows have been offered for purposes of example and discussion. Substantial flexibility is provided in that any suitable arrangements, chronologies, configurations, and timing mechanisms may be provided without departing from the teachings of the present disclosure.

Note that with the examples provided herein, interaction may be described in terms of one, two, three, or more elements. However, this has been done for purposes of clarity and example only. In certain cases, it may be easier to describe one or more of the functionalities by only referencing a limited number of elements. It should be appreciated that the system and method and their teachings are readily scalable and can accommodate a large number of components, as well as more complicated/sophisticated arrangements and configurations. Accordingly, the examples provided should not limit the scope or inhibit the broad teachings of the system and method as potentially applied to a myriad of other architectures.

Although the present disclosure has been described in detail with reference to particular arrangements and configurations, these example configurations and arrangements may be changed significantly without departing from the scope of the present disclosure. Moreover, certain components may be combined, separated, eliminated, or added based on particular needs and implementations. Additionally, although the system and method have been illustrated with reference to particular elements and operations, these elements and operations may be replaced by any suitable architecture, protocols, and/or processes that achieve the intended functionality of the system and method.

Numerous other changes, substitutions, variations, alterations, and modifications may be ascertained to one skilled in the art and it is intended that the present disclosure encompass all such changes, substitutions, variations, alterations, and modifications as falling within the scope of the appended claims. In order to assist the United States Patent and Trademark Office (USPTO) and, additionally, any readers of any patent issued on this application in interpreting the claims appended hereto, Applicant wishes to note that the Applicant: (a) does not intend any of the appended claims to invoke paragraph six (6) of 35 U.S.C. section 112 as it exists on the date of the filing hereof unless the words “means for” or “step for” are specifically used in the particular claims; and (b) does not intend, by any statement in the specification, to limit this disclosure in any way that is not otherwise reflected in the appended claims.

1. A vacuum chamber comprising:
a testing chamber;
an X, Y, Z scanner system located in the testing chamber with a radio frequency probe mounted on a top portion of the X, Y, Z scanner system;
a cylindrical thermal shroud to house a device under test, wherein the cylindrical thermal shroud is configured as an anechoic chamber; and
a movable thermal/radiation shield between the testing chamber and the cylindrical thermal shroud, wherein the movable thermal/radiation shield includes pleated blinds and an aperture that moves with the device under test.

2. The vacuum chamber of claim 1, wherein the aperture to allows terahertz frequency waves from a device under test to pass through the movable thermal/radiation shield and into the testing chamber.

3. The vacuum chamber of claim 1, wherein a first side of the movable thermal/radiation shield is coated with radio frequency absorbent material and a second side of the movable thermal/radiation shield is coated with multilayer insulation.

4. The vacuum chamber of claim 1, further comprising:
a counterweight system to unload the X, Y, Z scanner system from the testing chamber.

5. The vacuum chamber of claim 1, further comprising:
an intermediate eighty (80) Kelvin shroud on an outside portion of the cylindrical thermal shroud.

6. The vacuum chamber of claim 1, further comprising:
a device under test alignment system that includes pentaprisms and mirrors.

7. The vacuum chamber of claim 1, further comprising:
a thermo regulation system that distributes and regulates a flow of a liquid/gaseous nitrogen mixture.

8. The vacuum chamber of claim 5, further comprising:
a data acquisition system to collect data during testing of the device under test.

9. The vacuum chamber of claim 1, wherein the device under test is an antenna.

10. The vacuum chamber of claim 1, wherein the anechoic chamber is cooled to about four (4) Kelvin.

11. A system for cryogenic near field beam pattern measurement at terahertz frequencies, comprising:
a terahertz testing facility; and
a support structure for the terahertz testing facility, wherein the terahertz testing facility includes:
an anechoic chamber cooled by liquid nitrogen that includes an antenna under test;
a testing chamber that includes a scanning module; and
a thermal/radiation shield between the anechoic chamber and the testing chamber, wherein the thermal/radiation shield thermally separates the anechoic chamber and the testing chamber, wherein, during testing of the antenna under test, the environment inside the anechoic chamber and the testing chamber is a vacuum environment.

12. The system of claim 11, wherein the thermal/radiation shield includes pleated blinds and the pleated blinds help to alleviating risk of reflections distorting beam pattern measurements.

13. The system of claim 12, wherein at least a portion of the thermal/radiation shield is coated with absorber material to help provide an eighty (80) Kelvin environment inside the anechoic chamber.

14. The system of claim 12, wherein an X,Y,Z-plane scanner system is secured to and moves with the thermal/radiation shield.

15. The system of claim 11, wherein the system simulates conditions in outer space and the antenna under test is an antenna of a satellite.

16. The system of claim 11, further comprising:
an alignment system.

17. The system of claim 11, wherein the anechoic chamber is cooled to about four (4) Kelvin.

18. A method comprising:
testing a device at a temperature and pressure that simulate conditions in outer space using a thermal vacuum chamber, the thermal vacuum chamber including:
an anechoic chamber that includes the device;
a testing chamber; and
a thermal/radiation shield between the anechoic chamber and the testing chamber, wherein the thermal/radiation shield thermally separates the anechoic chamber and the testing chamber and has an aperture that can move; and
moving a thermal/radiation shield between a first portion of the thermal vacuum chamber and a second portion of the thermal vacuum chamber, wherein the thermal/radiation shield includes pleated blinds and the pleated blinds help to alleviating risk of reflections distorting beam pattern measurements.

19. The method of claim 18, further comprising:
measuring a complex electric field, amplitude and phase, as a function of X Y positions in the X Y plane by moving the device either continuously or in steps to perform a raster scan.

20. The method of claim 19, wherein the device is mounted on a cryogenic rotation stage to orient the device towards the X,Y,Z-plane scanner system for different deflection angles configurations without breaking the vacuum in the anechoic chamber.
